(19) United States
(12) Patent Application Publication
(10) Pub. No.: US 2025/0357950 A1
(43) Pub. Date: Nov. 20, 2025

(54) DECODING A SIGNAL BASED ON SOFT SYNDROME DECODING TECHNIQUES

(71) Applicant: QUALCOMM Incorporated, San Diego, CA (US)

(72) Inventors: Wei YANG, San Diego, CA (US); Jing JIANG, San Diego, CA (US)

(21) Appl. No.: 18/663,882

(22) Filed: May 14, 2024

(51) Int. Cl. H03M 13/11; H03M 13/15

(52) U.S. Cl. CPC H03M 13/1125; H03M 13/1111; H03M 13/1575

(57) ABSTRACT

Methods, systems, and devices for wireless communications are described. The described techniques may enable a receiving device to perform syndrome-based decoding. For example, a modem component of the receiving device may receive an encoded message and generate a syndrome and one or more log likelihood ratios (LLRs) associated with the encoded message, including LLR magnitudes and a sign vector associated with the one or more LLRs. The modem component may output the syndrome and LLR magnitudes to a forward error correction (FEC) performing component, which may generate an error vector using the syndrome and the LLR magnitudes. The modem component may obtain the error vector from the FEC and may generate an information vector (e.g., a decoded message, a codeword) based on the error vector and the sign vector.

### TECHNICAL FIELD

The following relates to wireless communications, including decoding a signal based on soft syndrome decoding techniques.

### BACKGROUND

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM). A wireless multiple-access communications system may include one or more base stations, each supporting wireless communication for communication devices, which may be known as user equipment (UE).

### SUMMARY

The described techniques relate to improved methods, systems, devices, and apparatuses that support decoding a signal based on soft syndrome decoding techniques. For example, the described techniques may enable a receiving device to perform syndrome-based decoding. For example, a modem component of the receiving device may receive an encoded message and generate a syndrome and one or more log likelihood ratios (LLRs) associated with the encoded message, including LLR magnitudes and a sign vector associated with the one or more LLRs. The modem component may output the syndrome and LLR magnitudes to a forward error correction (FEC) performing component, which may generate an error vector using the syndrome and the LLR magnitudes. The modem component may obtain the error vector from the FEC and may generate an information vector (e.g., a decoded message, a codeword) based on the error vector and the sign vector.

A method for wireless communications by an apparatus is described. The method may include receiving a signal including a set of multiple encoded bits, generating, from the signal, a set of multiple LLRs of the set of multiple encoded bits, where the set of multiple LLRs include a sign vector associated with the set of multiple LLRs and a set of multiple LLR magnitudes associated with the set of multiple LLRs, computing a set of multiple syndromes based on the sign vector, computing an error vector based on the set of multiple syndromes and the set of multiple LLR magnitudes, and outputting a set of multiple information bits based on the error vector and the sign vector.

An apparatus for wireless communications is described. The apparatus may include one or more memories storing processor executable code, and one or more processors coupled with (e.g., operatively, communicatively, functionally, electronically, or electrically) the one or more memories. The one or more processors may individually or collectively be operable to execute the code (e.g., directly, indirectly, after pre-processing, without pre-processing) to cause the apparatus to receive a signal including a set of multiple encoded bits, generate, from the signal, a set of multiple LLRs of the set of multiple encoded bits, where the set of multiple LLRs include a sign vector associated with the set of multiple LLRs and a set of multiple LLR magnitudes associated with the set of multiple LLRs, compute a set of multiple syndromes based on the sign vector, compute an error vector based on the set of multiple syndromes and the set of multiple LLR magnitudes, and output a set of multiple information bits based on the error vector and the sign vector.

Another apparatus for wireless communications is described. The apparatus may include means for receiving a signal including a set of multiple encoded bits, means for generating, from the signal, a set of multiple LLRs of the set of multiple encoded bits, where the set of multiple LLRs include a sign vector associated with the set of multiple LLRs and a set of multiple LLR magnitudes associated with the set of multiple LLRs, means for computing a set of multiple syndromes based on the sign vector, means for computing an error vector based on the set of multiple syndromes and the set of multiple LLR magnitudes, and means for outputting a set of multiple information bits based on the error vector and the sign vector.

A non-transitory computer-readable medium storing code for wireless communications is described. The code may include instructions executable by one or more processors (e.g., directly, indirectly, after pre-processing, without pre-processing) to receive a signal including a set of multiple encoded bits, generate, from the signal, a set of multiple LLRs of the set of multiple encoded bits, where the set of multiple LLRs include a sign vector associated with the set of multiple LLRs and a set of multiple LLR magnitudes associated with the set of multiple LLRs, compute a set of multiple syndromes based on the sign vector, compute an error vector based on the set of multiple syndromes and the set of multiple LLR magnitudes, and output a set of multiple information bits based on the error vector and the sign vector.

Some examples of the method, apparatus, and non-transitory computer-readable medium described herein may further include operations, features, means, or instructions for outputting, to a decoder, the set of multiple syndromes and the set of multiple LLR magnitudes, where computing the error vector includes and computing, by the decoder, the error vector based on the set of multiple syndromes and the set of multiple LLR magnitudes.

In some examples of the method, apparatus, and non-transitory computer-readable medium described herein, outputting the set of multiple syndromes and the set of multiple LLR magnitudes may include operations, features, means, or instructions for outputting a quantity of bits that may be less than a product of a code length associated with the signal and a quantization level associated with the signal, where the quantity of bits may be based on a coding rate of the signal.

In some examples of the method, apparatus, and non-transitory computer-readable medium described herein, the decoder may be a FEC decoder associated with a FEC code used to generate the set of multiple encoded bits.

Some examples of the method, apparatus, and non-transitory computer-readable medium described herein may further include operations, features, means, or instructions for outputting, by a decoder to a modem, the error vector, where outputting the set of multiple information bits further includes and outputting, by the modem, the set of multiple information bits based on the error vector.

In some examples of the method, apparatus, and non-transitory computer-readable medium described herein, computing the error vector may include operations, features, means, or instructions for performing belief propagation on a tanner graph, where the tanner graph includes a set of multiple check nodes each corresponding to one of the set of multiple syndromes and a set of multiple variable nodes each corresponding to one of the set of multiple LLR magnitudes.

In some examples of the method, apparatus, and non-transitory computer-readable medium described herein, outputting the set of multiple information bits may include operations, features, means, or instructions for computing a codeword vector, where the codeword vector includes a sum of the error vector and the sign vector.

In some examples of the method, apparatus, and non-transitory computer-readable medium described herein, receiving the signal including the set of multiple encoded bits may include operations, features, means, or instructions for receiving the set of multiple encoded bits including one or more punctured bits, where the sign vector may be generated based on the one or more punctured bits.

Some examples of the method, apparatus, and non-transitory computer-readable medium described herein may further include operations, features, means, or instructions for generating, using a random value generator, one or more sign values corresponding to each of the one or more punctured bits.

Some examples of the method, apparatus, and non-transitory computer-readable medium described herein may further include operations, features, means, or instructions for generating the sign vector, where one or more values of the sign vector corresponding to the one or more punctured bits may be equal to a predefined value.

A method for wireless communications by a modem of a wireless device is described. The method may include receiving a signal including a set of multiple encoded bits, generating, from the signal, a set of multiple LLRs of the set of multiple encoded bits, where the set of multiple LLRs include a sign vector associated with the set of multiple LLRs and a set of multiple LLR magnitudes associated with the set of multiple LLRs, computing a set of multiple syndromes based on the sign vector, outputting the set of multiple syndromes and the set of multiple LLR magnitudes, obtaining an error vector based on the set of multiple syndromes and the set of multiple LLR magnitudes, and outputting a set of multiple information bits based on the error vector and the sign vector.

A modem of a wireless device for wireless communications is described. The modem of a wireless device may include one or more memories storing processor executable code, and one or more processors coupled with (e.g., operatively, communicatively, functionally, electronically, or electrically) the one or more memories. The one or more processors may individually or collectively be operable to execute the code (e.g., directly, indirectly, after pre-processing, without pre-processing) to cause the modem of a wireless device to receive a signal including a set of multiple encoded bits, generate, from the signal, a set of multiple LLRs of the set of multiple encoded bits, where the set of multiple LLRs include a sign vector associated with the set of multiple LLRs and a set of multiple LLR magnitudes associated with the set of multiple LLRs, compute a set of multiple syndromes based on the sign vector, output the set of multiple syndromes and the set of multiple LLR magnitudes, obtain an error vector based on the set of multiple syndromes and the set of multiple LLR magnitudes, and output a set of multiple information bits based on the error vector and the sign vector.

Another modem of a wireless device for wireless communications is described. The modem of a wireless device may include means for receiving a signal including a set of multiple encoded bits, means for generating, from the signal, a set of multiple LLRs of the set of multiple encoded bits, where the set of multiple LLRs include a sign vector associated with the set of multiple LLRs and a set of multiple LLR magnitudes associated with the set of multiple LLRs, means for computing a set of multiple syndromes based on the sign vector, means for outputting the set of multiple syndromes and the set of multiple LLR magnitudes, means for obtaining an error vector based on the set of multiple syndromes and the set of multiple LLR magnitudes, and means for outputting a set of multiple information bits based on the error vector and the sign vector.

A non-transitory computer-readable medium storing code for wireless communications is described. The code may include instructions executable by one or more processors (e.g., directly, indirectly, after pre-processing, without pre-processing) to receive a signal including a set of multiple encoded bits, generate, from the signal, a set of multiple LLRs of the set of multiple encoded bits, where the set of multiple LLRs include a sign vector associated with the set of multiple LLRs and a set of multiple LLR magnitudes associated with the set of multiple LLRs, compute a set of multiple syndromes based on the sign vector, output the set of multiple syndromes and the set of multiple LLR magnitudes, obtain an error vector based on the set of multiple syndromes and the set of multiple LLR magnitudes, and output a set of multiple information bits based on the error vector and the sign vector.

In some examples of the method, modems of a wireless device, and non-transitory computer-readable medium described herein, outputting the set of multiple information bits may include operations, features, means, or instructions for computing a codeword vector, where the codeword vector includes a sum of the error vector and the sign vector.

In some examples of the method, modems of a wireless device, and non-transitory computer-readable medium described herein, receiving the signal including the set of multiple encoded bits may include operations, features, means, or instructions for receiving the set of multiple encoded bits including one or more punctured bits, where generating the sign vector may be based on the one or more punctured bits.

Some examples of the method, modems of a wireless device, and non-transitory computer-readable medium described herein may further include operations, features, means, or instructions for generating, using a random value generator, one or more sign values corresponding to each of the one or more punctured bits.

Some examples of the method, modems of a wireless device, and non-transitory computer-readable medium described herein may further include operations, features, means, or instructions for generating the sign vector, where one or more values of the sign vector corresponding to the one or more punctured bits may be equal to 0.

In some examples of the method, modems of a wireless device, and non-transitory computer-readable medium described herein, outputting the set of multiple syndromes and the set of multiple LLR magnitudes may include operations, features, means, or instructions for outputting a quantity of bits that may be less than a product of a code length associated with the signal and a quantization level associated with the signal, where the quantity of bits may be based on a coding rate of the signal.

A method for wireless communications by a decoder is described. The method may include obtaining a set of multiple syndromes associated with a signal and a set of multiple LLR magnitudes that correspond to a set of multiple LLRs associated with the signal, the signal including a set of multiple encoded bits, where the set of multiple LLRs and the set of multiple syndromes are associated with the set of multiple encoded bits, computing an error vector based on the set of multiple syndromes and the set of multiple LLR magnitudes, and outputting the error vector.

A decoder for wireless communications is described. The decoder may include one or more memories storing processor executable code, and one or more processors coupled with (e.g., operatively, communicatively, functionally, electronically, or electrically) the one or more memories. The one or more processors may individually or collectively be operable to execute the code (e.g., directly, indirectly, after pre-processing, without pre-processing) to cause the decoder to obtain a set of multiple syndromes associated with a signal and a set of multiple LLR magnitudes that correspond to a set of multiple LLRs associated with the signal, the signal including a set of multiple encoded bits, where the set of multiple LLRs and the set of multiple syndromes are associated with the set of multiple encoded bits, compute an error vector based on the set of multiple syndromes and the set of multiple LLR magnitudes, and output the error vector.

Another decoder for wireless communications is described. The decoder may include means for obtaining a set of multiple syndromes associated with a signal and a set of multiple LLR magnitudes that correspond to a set of multiple LLRs associated with the signal, the signal including a set of multiple encoded bits, where the set of multiple LLRs and the set of multiple syndromes are associated with the set of multiple encoded bits, means for computing an error vector based on the set of multiple syndromes and the set of multiple LLR magnitudes, and means for outputting the error vector.

A non-transitory computer-readable medium storing code for wireless communications is described. The code may include instructions executable by one or more processors (e.g., directly, indirectly, after pre-processing, without pre-processing) to obtain a set of multiple syndromes associated with a signal and a set of multiple LLR magnitudes that correspond to a set of multiple LLRs associated with the signal, the signal including a set of multiple encoded bits, where the set of multiple LLRs and the set of multiple syndromes are associated with the set of multiple encoded bits, compute an error vector based on the set of multiple syndromes and the set of multiple LLR magnitudes, and output the error vector.

In some examples of the method, decoders, and non-transitory computer-readable medium described herein, computing the error vector may include operations, features, means, or instructions for performing belief propagation on a tanner graph, where the tanner graph includes a set of multiple check nodes each corresponding to one of the set of multiple syndromes and a set of multiple variable nodes each corresponding to one of the set of multiple LLR magnitudes.

In some examples of the method, decoders, and non-transitory computer-readable medium described herein, obtaining the set of multiple syndromes and the set of multiple LLR magnitudes may include operations, features, means, or instructions for obtaining a quantity of bits that may be less than a product of a code length associated with the signal and a quantization level associated with the signal, where the quantity of bits may be based on a coding rate of the signal.

In some examples of the method, decoders, and non-transitory computer-readable medium described herein, the decoder may be a FEC decoder associated with a FEC code used to generate the set of multiple encoded bits.

### BRIEF DESCRIPTION OF THE DRAWINGS

FIG. 1 shows an example of a wireless communications system that supports decoding a signal based on soft syndrome decoding techniques in accordance with one or more aspects of the present disclosure.

FIG. 2 shows an example of a wireless communications system that supports decoding a signal based on soft syndrome decoding techniques in accordance with one or more aspects of the present disclosure.

FIG. 3 shows an example of a tanner graph that supports decoding a signal based on soft syndrome decoding techniques in accordance with one or more aspects of the present disclosure.

FIG. 4 shows an example of a process flow that supports decoding a signal based on soft syndrome decoding techniques in accordance with one or more aspects of the present disclosure.

FIGS. 5 and 6 show block diagrams of devices that support decoding a signal based on soft syndrome decoding techniques in accordance with one or more aspects of the present disclosure.

FIG. 7 shows a block diagram of a communications manager that supports decoding a signal based on soft syndrome decoding techniques in accordance with one or more aspects of the present disclosure.

FIG. 8 shows a diagram of a system including a device that supports decoding a signal based on soft syndrome decoding techniques in accordance with one or more aspects of the present disclosure.

FIGS. 9 through 13 show flowcharts illustrating methods that support decoding a signal based on soft syndrome decoding techniques in accordance with one or more aspects of the present disclosure.

### DETAILED DESCRIPTION

In some wireless communication systems, a receiving device (e.g., a network entity, a user equipment (UE)) may receive an encoded message from a transmitting device. The receiving device may decode the message using one or more decoding components (e.g., a modem component, memory, forward error correction (FEC) performing hardware). In some examples, a latency associated with performing decoding may be based on a bandwidth available at interfaces between the decoding components. Accordingly, exchanging or offloading decoding information between decoding components may increase latency and decrease a throughput of the system. Additionally, some components (e.g., FEC performing hardware) may be less secure than other components (e.g., the modem), and offloading information to the FEC performing hardware may decrease a security of the system.

Techniques described herein may enable the receiving device to perform syndrome-based decoding. For example, a modem component of the receiving device may receive the encoded message and generate one or more log likelihood ratios (LLRs) associated with the encoded message, including LLR magnitudes and a sign vector associated with the one or more LLRs. The modem component may generate a syndrome using the sign vector. The modem component may output the syndrome and LLR magnitudes to an FEC performing component, which may generate an error vector using the syndrome and the LLR magnitudes. The modem component may obtain the error vector from the FEC and may generate an information vector (e.g., a decoded message, a codeword) based on the error vector and the sign vector. Accordingly, the receiving device may exchange relatively less information via interfaces between components, which may decrease latency and throughput and increase security of the wireless communication system.

Aspects of the disclosure are initially described in the context of wireless communications systems. Aspects of the disclosure are further illustrated by and described with reference to tanner graphs, process flows, apparatus diagrams, system diagrams, and flowcharts that relate to decoding a signal based on soft syndrome decoding techniques.

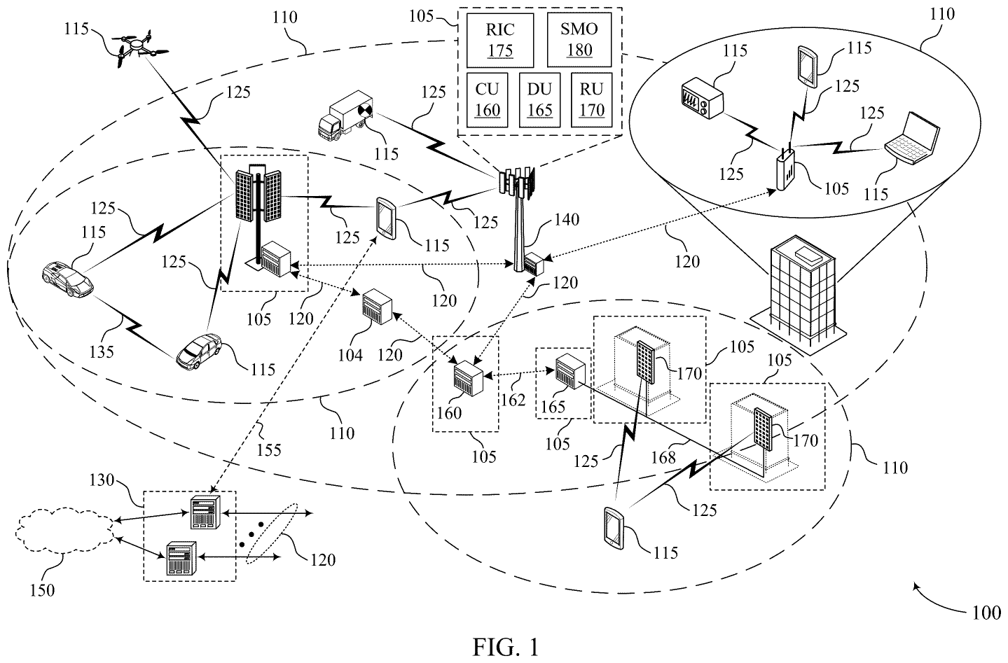

FIG. 1 shows an example of a wireless communications system 100 that supports decoding a signal based on soft syndrome decoding techniques in accordance with one or more aspects of the present disclosure. The wireless communications system 100 may include one or more devices, such as one or more network devices (e.g., network entities 105), one or more UEs 115, and a core network 130. In some examples, the wireless communications system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communications system 100 and may include devices in different forms or having different capabilities. In various examples, a network entity 105 may be referred to as a network element, a mobility element, a radio access network (RAN) node, or network equipment, among other nomenclature. In some examples, network entities 105 and UEs 115 may wirelessly communicate via communication link(s) 125 (e.g., a radio frequency (RF) access link). For example, a network entity 105 may support a coverage area 110 (e.g., a geographic coverage area) over which the UEs 115 and the network entity 105 may establish the communication link(s) 125. The coverage area 110 may be an example of a geographic area over which a network entity 105 and a UE 115 may support the communication of signals according to one or more radio access technologies (RATs).

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be capable of supporting communications with various types of devices in the wireless communications system 100 (e.g., other wireless communication devices, including UEs 115 or network entities 105), as shown in FIG. 1.

As described herein, a node of the wireless communications system 100, which may be referred to as a network node, or a wireless node, may be a network entity 105 (e.g., any network entity described herein), a UE 115 (e.g., any UE described herein), a network controller, an apparatus, a device, a computing system, one or more components, or another suitable processing entity configured to perform any of the techniques described herein. For example, a node may be a UE 115. As another example, a node may be a network entity 105. As another example, a first node may be configured to communicate with a second node or a third node. In one aspect of this example, the first node may be a UE 115, the second node may be a network entity 105, and the third node may be a UE 115. In another aspect of this example, the first node may be a UE 115, the second node may be a network entity 105, and the third node may be a network entity 105. In yet other aspects of this example, the first, second, and third nodes may be different relative to these examples. Similarly, reference to a UE 115, network entity 105, apparatus, device, computing system, or the like may include disclosure of the UE 115, network entity 105, apparatus, device, computing system, or the like being a node. For example, disclosure that a UE 115 is configured to receive information from a network entity 105 also discloses that a first node is configured to receive information from a second node.

In some examples, network entities 105 may communicate with a core network 130, or with one another, or both. For example, network entities 105 may communicate with the core network 130 via backhaul communication link(s) 120 (e.g., in accordance with an S1, N2, N3, or other interface protocol). In some examples, network entities 105 may communicate with one another via backhaul communication link(s) 120 (e.g., in accordance with an X2, Xn, or other interface protocol) either directly (e.g., directly between network entities 105) or indirectly (e.g., via the core network 130). In some examples, network entities 105 may communicate with one another via a midhaul communication link 162 (e.g., in accordance with a midhaul interface protocol) or a fronthaul communication link 168 (e.g., in accordance with a fronthaul interface protocol), or any combination thereof. The backhaul communication link(s) 120, midhaul communication links 162, or fronthaul communication links 168 may be or include one or more wired links (e.g., an electrical link, an optical fiber link) or one or more wireless links (e.g., a radio link, a wireless optical link), among other examples or various combinations thereof. A UE 115 may communicate with the core network 130 via a communication link 155.

One or more of the network entities 105 or network equipment described herein may include or may be referred to as a base station 140 (e.g., a base transceiver station, a radio base station, an NR base station, an access point, a radio transceiver, a NodeB, an eNodeB (eNB), a next-generation NodeB or giga-NodeB (either of which may be referred to as a gNB), a 5G NB, a next-generation eNB (ng-eNB), a Home NodeB, a Home eNodeB, or other suitable terminology). In some examples, a network entity 105 (e.g., a base station 140) may be implemented in an aggregated (e.g., monolithic, standalone) base station architecture, which may be configured to utilize a protocol stack that is physically or logically integrated within one network entity (e.g., a network entity 105 or a single RAN node, such as a base station 140).

In some examples, a network entity 105 may be implemented in a disaggregated architecture (e.g., a disaggregated base station architecture, a disaggregated RAN architecture), which may be configured to utilize a protocol stack that is physically or logically distributed among multiple network entities (e.g., network entities 105), such as an integrated access and backhaul (IAB) network, an open RAN (O-RAN) (e.g., a network configuration sponsored by the O-RAN Alliance), or a virtualized RAN (vRAN) (e.g., a cloud RAN (C-RAN)). For example, a network entity 105 may include one or more of a central unit (CU), such as a CU 160, a distributed unit (DU), such as a DU 165, a radio unit (RU), such as an RU 170, a RAN Intelligent Controller (RIC), such as an RIC 175 (e.g., a Near-Real Time RIC (Near-RT RIC), a Non-Real Time RIC (Non-RT RIC)), a Service Management and Orchestration (SMO) system, such as an SMO system 180, or any combination thereof. An RU 170 may also be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (e.g., separate physical locations). In some examples, one or more of the network entities 105 of a disaggregated RAN architecture may be implemented as virtual units (e.g., a virtual CU (VCU), a virtual DU (VDU), a virtual RU (VRU)).

The split of functionality between a CU 160, a DU 165, and an RU 170 is flexible and may support different functionalities depending on which functions (e.g., network layer functions, protocol layer functions, baseband functions, RF functions, or any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some examples, the CU 160 may host upper protocol layer (e.g., layer 3 (L3), layer 2 (L2)) functionality and signaling (e.g., Radio Resource Control (RRC), service data adaptation protocol (SDAP), Packet Data Convergence Protocol (PDCP)). The CU 160 (e.g., one or more CUs) may be connected to a DU 165 (e.g., one or more DUs) or an RU 170 (e.g., one or more RUs), or some combination thereof, and the DUs 165, RUs 170, or both may host lower protocol layers, such as layer 1 (L1) (e.g., physical (PHY) layer) or L2 (e.g., radio link control (RLC) layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (e.g., via one or multiple different RUs, such as an RU 170). In some cases, a functional split between a CU 160 and a DU 165 or between a DU 165 and an RU 170 may be within a protocol layer (e.g., some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to a DU 165 via a midhaul communication link 162 (e.g., F1, F1-c, F1-u), and a DU 165 may be connected to an RU 170 via a fronthaul communication link 168 (e.g., open fronthaul (FH) interface). In some examples, a midhaul communication link 162 or a fronthaul communication link 168 may be implemented in accordance with an interface (e.g., a channel) between layers of a protocol stack supported by respective network entities (e.g., one or more of the network entities 105) that are in communication via such communication links.

In some wireless communications systems (e.g., the wireless communications system 100), infrastructure and spectral resources for radio access may support wireless backhaul link capabilities to supplement wired backhaul connections, providing an IAB network architecture (e.g., to a core network 130). In some cases, in an IAB network, one or more of the network entities 105 (e.g., network entities 105 or IAB node(s) 104) may be partially controlled by each other. The IAB node(s) 104 may be referred to as a donor entity or an IAB donor. A DU 165 or an RU 170 may be partially controlled by a CU 160 associated with a network entity 105 or base station 140 (such as a donor network entity or a donor base station). The one or more donor entities (e.g., IAB donors) may be in communication with one or more additional devices (e.g., IAB node(s) 104) via supported access and backhaul links (e.g., backhaul communication link(s) 120). IAB node(s) 104 may include an IAB mobile termination (IAB-MT) controlled (e.g., scheduled) by one or more DUs (e.g., DUs 165) of a coupled IAB donor. An IAB-MT may be equipped with an independent set of antennas for relay of communications with UEs 115 or may share the same antennas (e.g., of an RU 170) of IAB node(s) 104 used for access via the DU 165 of the IAB node(s) 104 (e.g., referred to as virtual IAB-MT (vIAB-MT)). In some examples, the IAB node(s) 104 may include one or more DUs (e.g., DUs 165) that support communication links with additional entities (e.g., IAB node(s) 104, UEs 115) within the relay chain or configuration of the access network (e.g., downstream). In such cases, one or more components of the disaggregated RAN architecture (e.g., the IAB node(s) 104 or components of the IAB node(s) 104) may be configured to operate according to the techniques described herein.

In the case of the techniques described herein applied in the context of a disaggregated RAN architecture, one or more components of the disaggregated RAN architecture may be configured to support test as described herein. For example, some operations described as being performed by a UE 115 or a network entity 105 (e.g., a base station 140) may additionally, or alternatively, be performed by one or more components of the disaggregated RAN architecture (e.g., components such as an IAB node, a DU 165, a CU 160, an RU 170, an RIC 175, an SMO system 180).

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a multimedia/entertainment device (e.g., a radio, a MP3 player, or a video device), a camera, a gaming device, a navigation/positioning device (e.g., GNSS (global navigation satellite system) devices based on, for example, GPS (global positioning system), Beidou, GLONASS, or Galileo, or a terrestrial-based device), a tablet computer, a laptop computer, a netbook, a smartbook, a personal computer, a smart device, a wearable device (e.g., a smart watch, smart clothing, smart glasses, virtual reality goggles, a smart wristband, smart jewelry (e.g., a smart ring, a smart bracelet)), a drone, a robot/robotic device, a vehicle, a vehicular device, a meter (e.g., parking meter, electric meter, gas meter, water meter), a monitor, a gas pump, an appliance (e.g., kitchen appliance, washing machine, dryer), a location tag, a medical/healthcare device, an implant, a sensor/actuator, a display, or any other suitable device configured to communicate via a wireless or wired medium. In some examples, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, vehicles, or meters, among other examples.

The UEs 115 described herein may be able to communicate with various types of devices, such as UEs 115 that may sometimes operate as relays, as well as the network entities 105 and the network equipment including macro eNBs or gNBs, small cell eNBs or gNBs, or relay base stations, among other examples, as shown in FIG. 1.

The UEs 115 and the network entities 105 may wirelessly communicate with one another via the communication link(s) 125 (e.g., one or more access links) using resources associated with one or more carriers. The term “carrier” may refer to a set of RF spectrum resources having a defined PHY layer structure for supporting the communication link(s) 125. For example, a carrier used for the communication link(s) 125 may include a portion of an RF spectrum band (e.g., a bandwidth part (BWP)) that is operated according to one or more PHY layer channels for a given RAT (e.g., LTE, LTE-A, LTE-A Pro, NR). Each PHY layer channel may carry acquisition signaling (e.g., synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (e.g., entity, sub-entity) of a network entity 105. For example, the terms “transmitting,” “receiving,” or “communicating,” when referring to a network entity 105, may refer to any portion of a network entity 105 (e.g., a base station 140, a CU 160, a DU 165, a RU 170) of a RAN communicating with another device (e.g., directly or via one or more other network entities, such as one or more of the network entities 105).

Signal waveforms transmitted via a carrier may be made up of multiple subcarriers (e.g., using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (e.g., a duration of one modulation symbol) and one subcarrier, in which case the symbol period and subcarrier spacing may be inversely related. The quantity of bits carried by each resource element may depend on the modulation scheme (e.g., the order of the modulation scheme, the coding rate of the modulation scheme, or both), such that a relatively higher quantity of resource elements (e.g., in a transmission duration) and a relatively higher order of a modulation scheme may correspond to a relatively higher rate of communication. A wireless communications resource may refer to a combination of an RF spectrum resource, a time resource, and a spatial resource (e.g., a spatial layer, a beam), and the use of multiple spatial resources may increase the data rate or data integrity for communications with a UE 115.

One or more numerologies for a carrier may be supported, and a numerology may include a subcarrier spacing (Δf) and a cyclic prefix. A carrier may be divided into one or more BWPs having the same or different numerologies. In some examples, a UE 115 may be configured with multiple BWPs. In some examples, a single BWP for a carrier may be active at a given time and communications for the UE 115 may be restricted to one or more active BWPs.

The time intervals for the network entities 105 or the UEs 115 may be expressed in multiples of a basic time unit which may, for example, refer to a sampling period of Tₛ=1/(Δfₘₐₓ·N_{f}) seconds, for which Δfₘₐₓ may represent a supported subcarrier spacing, and N_{f} may represent a supported discrete Fourier transform (DFT) size. Time intervals of a communications resource may be organized according to radio frames each having a specified duration (e.g., 10 milliseconds (ms)). Each radio frame may be identified by a system frame number (SFN) (e.g., ranging from 0 to 1023).

Each frame may include multiple consecutively-numbered subframes or slots, and each subframe or slot may have the same duration. In some examples, a frame may be divided (e.g., in the time domain) into subframes, and each subframe may be further divided into a quantity of slots. Alternatively, each frame may include a variable quantity of slots, and the quantity of slots may depend on subcarrier spacing. Each slot may include a quantity of symbol periods (e.g., depending on the length of the cyclic prefix prepended to each symbol period). In some wireless communications systems, such as the wireless communications system 100, a slot may further be divided into multiple mini-slots associated with one or more symbols. Excluding the cyclic prefix, each symbol period may be associated with one or more (e.g., N_{f}) sampling periods. The duration of a symbol period may depend on the subcarrier spacing or frequency band of operation.

A subframe, a slot, a mini-slot, or a symbol may be the smallest scheduling unit (e.g., in the time domain) of the wireless communications system 100 and may be referred to as a transmission time interval (TTI). In some examples, the TTI duration (e.g., a quantity of symbol periods in a TTI) may be variable. Additionally, or alternatively, the smallest scheduling unit of the wireless communications system 100 may be dynamically selected (e.g., in bursts of shortened TTIs (STTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (e.g., a control resource set (CORESET)) for a physical control channel may be defined by a set of symbol periods and may extend across the system bandwidth or a subset of the system bandwidth of the carrier. One or more control regions (e.g., CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (e.g., control channel elements (CCEs)) associated with encoded information for a control information format having a given payload size. Search space sets may include common search space sets configured for sending control information to UEs 115 (e.g., one or more UEs) or may include UE-specific search space sets for sending control information to a UE 115 (e.g., a specific UE).

In some examples, a network entity 105 (e.g., a base station 140, an RU 170) may be movable and therefore provide communication coverage for a moving coverage area, such as the coverage area 110. In some examples, coverage areas 110 (e.g., different coverage areas) associated with different technologies may overlap, but the coverage areas 110 (e.g., different coverage areas) may be supported by the same network entity (e.g., a network entity 105). In some other examples, overlapping coverage areas, such as a coverage area 110, associated with different technologies may be supported by different network entities (e.g., the network entities 105). The wireless communications system 100 may include, for example, a heterogeneous network in which different types of the network entities 105 support communications for coverage areas 110 (e.g., different coverage areas) using the same or different RATs.

Some UEs 115, such as MTC or IoT devices, may be relatively low cost or low complexity devices and may provide for automated communication between machines (e.g., via Machine-to-Machine (M2M) communication). M2M communication or MTC may refer to data communication technologies that allow devices to communicate with one another or a network entity 105 (e.g., a base station 140) without human intervention. In some examples, M2M communication or MTC may include communications from devices that integrate sensors or meters to measure or capture information and relay such information to a central server or application program that uses the information or presents the information to humans interacting with the application program. Some UEs 115 may be designed to collect information or enable automated behavior of machines or other devices. Examples of applications for MTC devices include smart metering, inventory monitoring, water level monitoring, equipment monitoring, healthcare monitoring, wildlife monitoring, weather and geological event monitoring, fleet management and tracking, remote security sensing, physical access control, and transaction-based business charging. In an aspect, techniques disclosed herein may be applicable to MTC or IoT UEs. MTC or IoT UEs may include MTC/enhanced MTC (eMTC, also referred to as CAT-M, Cat M1) UEs, NB-IoT (also referred to as CAT NB1) UEs, as well as other types of UEs. cMTC and NB-IoT may refer to future technologies that may evolve from or may be based on these technologies. For example, eMTC may include FeMTC (further eMTC), cFeMTC (enhanced further eMTC), and mMTC (massive MTC), and NB-IoT may include eNB-IoT (enhanced NB-IoT), and FeNB-IoT (further enhanced NB-IoT).

The wireless communications system 100 may be configured to support ultra-reliable communications or low-latency communications, or various combinations thereof. For example, the wireless communications system 100 may be configured to support ultra-reliable low-latency communications (URLLC). The UEs 115 may be designed to support ultra-reliable, low-latency, or critical functions. Ultra-reliable communications may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some examples, a UE 115 may be configured to support communicating directly with other UEs (e.g., one or more of the UEs 115) via a device-to-device (D2D) communication link, such as a D2D communication link 135 (e.g., in accordance with a peer-to-peer (P2P), D2D, or sidelink protocol). In some examples, one or more UEs 115 of a group that are performing D2D communications may be within the coverage area 110 of a network entity 105 (e.g., a base station 140, an RU 170), which may support aspects of such D2D communications being configured by (e.g., scheduled by) the network entity 105. In some examples, one or more UEs 115 of such a group may be outside the coverage area 110 of a network entity 105 or may be otherwise unable to or not configured to receive transmissions from a network entity 105. In some examples, groups of the UEs 115 communicating via D2D communications may support a one-to-many (1:M) system in which each UE 115 transmits to one or more of the UEs 115 in the group. In some examples, a network entity 105 may facilitate the scheduling of resources for D2D communications. In some other examples, D2D communications may be carried out between the UEs 115 without an involvement of a network entity 105.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (e.g., a mobility management entity (MME), an access and mobility management function (AMF)) and at least one user plane entity that routes packets or interconnects to external networks (e.g., a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (e.g., base stations 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communications system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communications using UHF waves may be associated with smaller antennas and shorter ranges (e.g., less than one hundred kilometers) compared to communications using the smaller frequencies and longer waves of the high frequency (HF) or very high frequency (VHF) portion of the spectrum below 300 MHz.

The wireless communications system 100 may also operate using a super high frequency (SHF) region, which may be in the range of 3 GHz to 30 GHz, also known as the centimeter band, or using an extremely high frequency (EHF) region of the spectrum (e.g., from 30 GHz to 300 GHz), also known as the millimeter band. In some examples, the wireless communications system 100 may support millimeter wave (mmW) communications between the UEs 115 and the network entities 105 (e.g., base stations 140, RUs 170), and EHF antennas of the respective devices may be smaller and more closely spaced than UHF antennas. In some examples, such techniques may facilitate using antenna arrays within a device. The propagation of EHF transmissions, however, may be subject to even greater attenuation and shorter range than SHF or UHF transmissions. The techniques disclosed herein may be employed across transmissions that use one or more different frequency regions, and designated use of bands across these frequency regions may differ by country or regulating body.

The wireless communications system 100 may utilize both licensed and unlicensed RF spectrum bands. For example, the wireless communications system 100 may employ License Assisted Access (LAA), LTE-Unlicensed (LTE-U) RAT, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some examples, operations using unlicensed bands may be based on a carrier aggregation configuration in conjunction with component carriers operating using a licensed band (e.g., LAA). Operations using unlicensed spectrum may include downlink transmissions, uplink transmissions, P2P transmissions, or D2D transmissions, among other examples.

A network entity 105 (e.g., a base station 140, an RU 170) or a UE 115 may be equipped with multiple antennas, which may be used to employ techniques such as transmit diversity, receive diversity, multiple-input multiple-output (MIMO) communications, or beamforming. The antennas of a network entity 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some examples, antennas or antenna arrays associated with a network entity 105 may be located at diverse geographic locations. A network entity 105 may include an antenna array with a set of rows and columns of antenna ports that the network entity 105 may use to support beamforming of communications with a UE 115. Likewise, a UE 115 may include one or more antenna arrays that may support various MIMO or beamforming operations. Additionally, or alternatively, an antenna panel may support RF beamforming for a signal transmitted via an antenna port.

Beamforming, which may also be referred to as spatial filtering, directional transmission, or directional reception, is a signal processing technique that may be used at a transmitting device or a receiving device (e.g., a network entity 105, a UE 115) to shape or steer an antenna beam (e.g., a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

A network entity 105 or a UE 115 may use beam sweeping techniques as part of beamforming operations. For example, a network entity 105 (e.g., a base station 140, an RU 170) may use multiple antennas or antenna arrays (e.g., antenna panels) to conduct beamforming operations for directional communications with a UE 115. Some signals (e.g., synchronization signals, reference signals, beam selection signals, or other control signals) may be transmitted by a network entity 105 multiple times along different directions. For example, the network entity 105 may transmit a signal according to different beamforming weight sets associated with different directions of transmission. Transmissions along different beam directions may be used to identify (e.g., by a transmitting device, such as a network entity 105, or by a receiving device, such as a UE 115) a beam direction for later transmission or reception by the network entity 105.

Some signals, such as data signals associated with a particular receiving device, may be transmitted by a transmitting device (e.g., a network entity 105 or a UE 115) along a single beam direction (e.g., a direction associated with the receiving device, such as another network entity 105 or UE 115). In some examples, the beam direction associated with transmissions along a single beam direction may be determined based on a signal that was transmitted along one or more beam directions. For example, a UE 115 may receive one or more of the signals transmitted by the network entity 105 along different directions and may report to the network entity 105 an indication of the signal that the UE 115 received with a highest signal quality or an otherwise acceptable signal quality.

In some examples, transmissions by a device (e.g., by a network entity 105 or a UE 115) may be performed using multiple beam directions, and the device may use a combination of digital precoding or beamforming to generate a combined beam for transmission (e.g., from a network entity 105 to a UE 115). The UE 115 may report feedback that indicates precoding weights for one or more beam directions, and the feedback may correspond to a configured set of beams across a system bandwidth or one or more sub-bands. The network entity 105 may transmit a reference signal (e.g., a cell-specific reference signal (CRS), a channel state information reference signal (CSI-RS)), which may be precoded or unprecoded. The UE 115 may provide feedback for beam selection, which may be a precoding matrix indicator (PMI) or codebook-based feedback (e.g., a multi-panel type codebook, a linear combination type codebook, a port selection type codebook). Although these techniques are described with reference to signals transmitted along one or more directions by a network entity 105 (e.g., a base station 140, an RU 170), a UE 115 may employ similar techniques for transmitting signals multiple times along different directions (e.g., for identifying a beam direction for subsequent transmission or reception by the UE 115) or for transmitting a signal along a single direction (e.g., for transmitting data to a receiving device).

A receiving device (e.g., a UE 115) may perform reception operations in accordance with multiple receive configurations (e.g., directional listening) when receiving various signals from a transmitting device (e.g., a network entity 105), such as synchronization signals, reference signals, beam selection signals, or other control signals. For example, a receiving device may perform reception in accordance with multiple receive directions by receiving via different antenna subarrays, by processing received signals according to different antenna subarrays, by receiving according to different receive beamforming weight sets (e.g., different directional listening weight sets) applied to signals received at multiple antenna elements of an antenna array, or by processing received signals according to different receive beamforming weight sets applied to signals received at multiple antenna elements of an antenna array, any of which may be referred to as “listening” according to different receive configurations or receive directions. In some examples, a receiving device may use a single receive configuration to receive along a single beam direction (e.g., when receiving a data signal). The single receive configuration may be aligned along a beam direction determined based on listening according to different receive configuration directions (e.g., a beam direction determined to have a highest signal strength, highest signal-to-noise ratio (SNR), or otherwise acceptable signal quality based on listening according to multiple beam directions).

The UEs 115 and the network entities 105 may support retransmissions of data to increase the likelihood that data is received successfully. Hybrid automatic repeat request (HARQ) feedback is one technique for increasing the likelihood that data is received correctly via a communication link (e.g., the communication link(s) 125, a D2D communication link 135). HARQ may include a combination of error detection (e.g., using a cyclic redundancy check (CRC)), FEC, and retransmission (e.g., automatic repeat request (ARQ)). HARQ may improve throughput at the MAC layer in relatively poor radio conditions (e.g., low signal-to-noise conditions). In some examples, a device may support same-slot HARQ feedback, in which case the device may provide HARQ feedback in a specific slot for data received via a previous symbol in the slot. In some other examples, the device may provide HARQ feedback in a subsequent slot, or according to some other time interval.

In some examples of the wireless communication system 100, a receiving device (e.g., a UE 115, a network entity 105) may perform syndrome-based decoding of an encoded message from a transmitting device (e.g., a UE 115, a network entity 105). For example, a modem component of the receiving device may receive the encoded message and generate one or more LLRs associated with the encoded message. The one or more LLRs may comprise a set of LLR magnitudes and a sign vector associated with the one or more LLRs. The modem component may generate a syndrome using the sign vector. The modem component may output the syndrome and LLR magnitudes to an FEC performing component, which may generate an error vector using the syndrome and the LLR magnitudes. The modem component may obtain the error vector from the FEC and may generate an information vector (e.g., a decoded message, a codeword) based on the error vector and the sign vector.

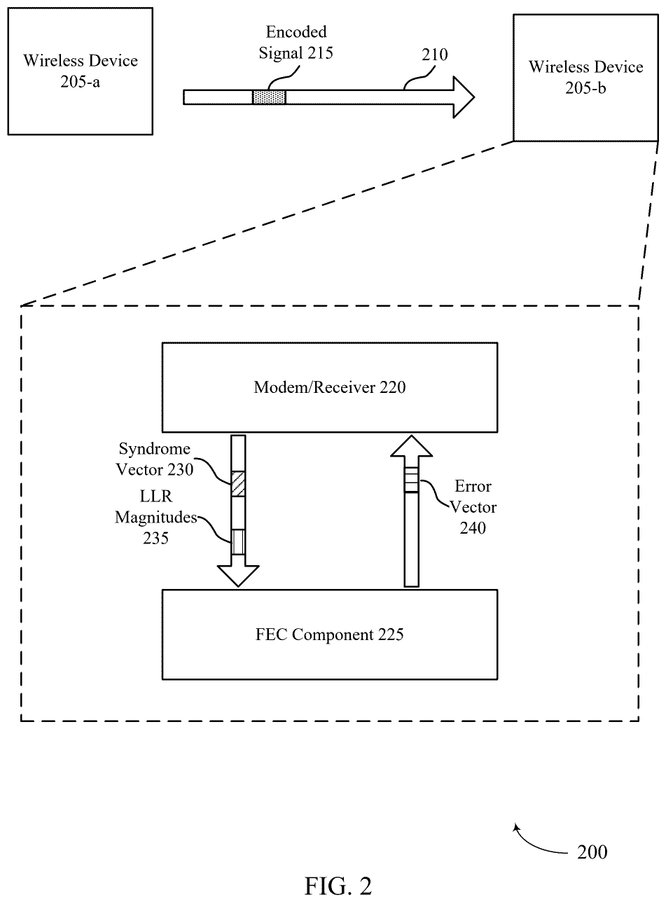

FIG. 2 shows an example of a wireless communications system 200 that supports decoding a signal based on soft syndrome decoding techniques in accordance with one or more aspects of the present disclosure. The wireless communications system 200 may implement or may be implemented by aspects of the wireless communications system 100. For example, the wireless communications system 200 may be implemented by a wireless device 205-a and a wireless device 205-b, which may be examples of a UE 115 or a network entity 105 as described with reference to FIG. 1.

In some examples of the wireless communications system 200, one or more wireless devices 205 (e.g., a wireless device 205-a, a wireless device 205-b) may use relatively higher throughput (e.g., 100 gigabits per second (Gbps) for UEs 115 and 1 terabit per second (Tbps) for a network entity 105) than some other wireless communications systems. To support the relatively higher throughput, the wireless devices 205 may use relatively larger amounts of computation for receiving signals. Accordingly, wireless devices 205 (e.g., UEs 115, network entities 105) may use heterogeneous hardware (e.g., combinations of central processing units (CPUs), graphics processing units (GPUs), application-specific integrated circuits (ASICs), field programmable gate arrays (FPGAs), digital signal processors (DSPs)) for computational tasks. That is, the wireless devices 205 may use different hardware to perform different computational tasks. Such heterogeneous hardware techniques may be implemented by devices such as computers, phones, base stations or other network entities, and data centers.

In some examples, the computational tasks at a receiving device may include channel decoding (e.g., decoding encoded signals received by the wireless device 205). For high throughput decoding, some wireless devices 205 (e.g., network entities 105) may use dedicated hardware accelerators (e.g., FPGAs) to perform channel coding and some other hardware to perform other tasks (e.g., other than channel coding). Some wireless devices 205 (e.g., UEs 115) may offload low density parity check (LDPC) decoding to a GPU or other hardware such as a DSP (e.g., if the GPU and DSP are not in use). In either case, a bottleneck associated with performing channel decoding in heterogeneous hardware systems may be related to outputting and obtaining information across interfaces between hardware components (e.g., rather than related to computation itself).

For example, a wireless device 205-b (e.g., a receiving device) may offload FEC decoding tasks from a modem/receiver 220 to another computation unit (e.g., an FEC component 225, which may be an example of a hardware accelerator, a GUP, a DSP, or a FPGA). However, a throughput of the interface between the modem/receiver 220 and the FEC component 225 may be limited by the bandwidth of the interface. Additionally, offloading decoding tasks to the FEC component 225 may be relatively less secure than performing decoding tasks at the modem/receiver 220. For example, a decoded result may include information bits, which may allow the FEC component 225 to obtain critical information about a communication.

In some examples, a wireless device 205 may use LDPC and belief propagation (BP) decoding to decode an encoded signal. As described herein, an LDPC code may be a linear code defined by a sparse parity check matrix (e.g., low-density). The wireless device 205 may decode the encoded signal based on message passing (e.g., BP, min-sum, offset min-sum) over a tanner graph, include one or more check nodes and one or more variable nodes. To decode the message, the decoder may use LLRs corresponding to a channel output. Accordingly, a bandwidth used to convey information to the decoder may be N*B, where N may be a quantity of coded bits of the channel output and B may be a bitwidth of the LLR values consumed by the decoder (e.g., a quantization per LLR).

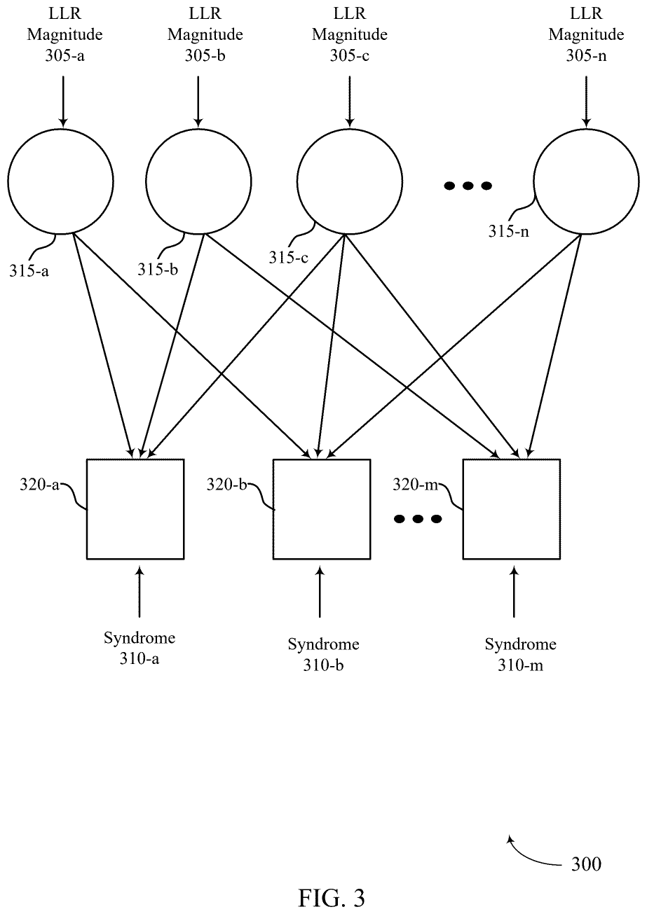

Additionally, or alternatively, the wireless device may use syndrome decoding to decode the encoded signal. For example, given a set of LLRs {Li} associated with a transmitted codeword {cᵢ}, the wireless device 205 may perform hard decision to obtain a hard decision vector r, where rᵢ=(1-sign (Lᵢ))/2. The wireless device may a linear code with a parity check matrix H, such that Hr=H (e+c)=He+0=He, where e may be defined as an error vector associated with the hard decision vector r (e.g., such that e=r−c) and Hr may be defined as the syndrome vector s. As described herein, a size of the parity check matrix H may be (N−K)*N, where N is the length of r, c, and e, K is a quantity of bits associated with a linear code, and the length of Hr is (N−K). A syndrome decoder may determine the error vector e based on the syndrome s (e.g., Hr), rather than based on the signal r. An amount of data used by a syndrome decoder may be relatively smaller than an amount of data used by another LDPC decoder. For example, a bandwidth used to convey the syndrome to the decoder may depend on (N−K), which may be relatively smaller than N for a high coding rate case (e.g., with K/N close to 1). An example of soft-syndrome BP decoding is described in further detail with reference to FIG. 3.

As illustrated with reference to FIG. 2, a wireless device 205-a may transmit an encoded signal 215 to a wireless device 205-b via a channel 210 between the wireless device 205-a and the wireless device 205-b. The wireless device 205-b may receive the encoded signal 215 (e.g., including a set of encoded information bits) at the modem/receiver 220 of the wireless device 205-b. The modem/receiver 220 may obtain a set of LLRs L for the encoded signal 215, which may include a set of LLR magnitudes 235 (e.g., {|Lᵢ|}) and a corresponding sign vector r (L) which may denote a hard decision of the LLRs (e.g., including a sign vector r_{info} corresponding to the encoded information bits). The modem/receiver 220 may generate a syndrome vector 230 (e.g., s) using the sign vector r (L) and a parity check matrix H according to s=Hr (L).

The modem/receiver 220 may communicate the syndrome vector 230 and the LLR magnitudes 235 to the FEC component 225. A quantity of bits used to communicate the syndrome vector 230 and the LLR magnitudes 235 may be N* (B−1)+(N−K)=N*B−K, which may be relatively smaller than N*B bits used to convey the full LLRs to the FEC component 225. As an illustrative example, for a bitwidth of 2 and a coding rate K/N of 0.93, soft-syndrome decoding may reduce communication overhead by 0.93/2 or 46.5% as compared to LDPC decoding. The FEC component 225 may therefore use a decoder (e.g., a soft-syndrome decoder, a syndrome BP decoder) to generate an error vector 240 (e.g., e_{info}) of the encoded information bits, as described with reference to FIG. 3. The FEC component 225 may return the error vector 240 to the modem/receiver 220.

The modem/receiver may combine the error vector e_{info} and the sign vector r_{info} (e.g., a sign vector used to generate the syndrome s, with values taken from a set {0,1}) on the information bits (e.g., the information portion of the signal) to obtain an information vector (e.g., a vector of decoded information bits) C_{info} according to C_{info}=T_{info}+e_{info}. Accordingly, the wireless device 205-b may obtain the decoded information bits without providing r_{info} (e.g., containing actual information of the payload of the encoded signal 215) to the FEC component 225. That is, the FEC component 225 may obtain an error pattern that is independent of any raw data included in the encoded signal 215, which may increase a security and privacy of the wireless communications system 200.

In some examples, to improve a performance of LDPC code designs, the wireless device 205-a may puncture one or more information bits (e.g., may not transmit the punctured bits over the channel 210 to the wireless device 205-b). The wireless device 205-b may set LLRs corresponding to the punctured information bits to 0 for the LDPC decoder. However, the LLRs corresponding to the punctured bits (e.g., punctured nodes) may not have a sign. Accordingly, the wireless device 205-b may set the sign of LLRs of the punctured bits to a predefined value to compute the sign vector r, and using this sign vector r to compute the syndrome vector 230 s. The modem/receiver 220 may not communicate the LLR magnitudes 235 of the punctured bits to the FEC component 225 (e.g., because the LLR magnitudes 235 of punctured bits may be 0). The FEC component 225 may use a magnitude of 0 as the magnitudes of the LLRs associated with the punctured information bits.

In some aspects, the wireless device 205-b may set the sign vector of the punctured bits r_{punc} to 0. That is, the modem/receiver 220 may compute the syndrome vector 230 using a portion of the parity check matrix Hₜₓ that is associated with transmitted bits (e.g., non-punctured bits). Hₜₓ may correspond to a submatrix comprising columns of the parity check matrix H that are associated with transmitted information or parity bits. In such examples, the error vector e corresponding to the punctured bits e_{punc} may comprise the true information bits corresponding to the punctured nodes (e.g., as e_{punc}=r_{punc}+C_{punc}=C_{punc}).

In some aspects, the modem/receiver 220 may generate (e.g., randomly generate) the sign vector corresponding to the punctured bits as r_{punc} and may compute the syndrome vector 230 s=Hr using the generated r_{punc} for the punctured (information) bits. The FEC component 225 may accordingly have access to e_{punc}=r_{punc}+C_{punc}, which may not contain any information about the values of the punctured information bits C_{punc} as the FEC component 225 may not have access to the generated r_{punc}. Accordingly, the generated r_{punc} may have a relatively higher security as compared to the r_{punc} set to 0. The modem/receiver 220 may obtain C_{punc} according to C_{punc}=e_{punc}+r_{punc}.

FIG. 3 shows an example of a tanner graph 300 that supports decoding a signal based on soft syndrome decoding techniques in accordance with one or more aspects of the present disclosure. The tanner graph 300 may implement or may be implemented by aspects of the wireless communications system 100 or the wireless communication system 200. For example, the tanner graph 300 may be implemented by one or more wireless devices, which may be examples of a UE 115 or a network entity 105 as described with reference to FIG. 1.

In some examples, a wireless device may perform soft-syndrome BP decoding to obtain an error vector e associated with a received encoded signal. The wireless device may perform the soft-syndrome BP decoding using a set of LLR magnitudes 305 (e.g., an LLR magnitude 305-a, an LLR magnitude 305-b, an LLR magnitude 305-c, and so on through an LLR magnitude 305-n, where n is a quantity of bits of the encoded signal) of a set of LLRs {Lᵢ} associated with the encoded signal. The wireless device may further use a vector of syndromes 310 s=Hr (L) (e.g., a syndrome 310-a, a syndrome 310-b, and so on through a syndrome 310-m, where m is the quantity n minus K, where K/n is the code rate), where r (L) denotes a hard decision, as described with reference to FIG. 2. A syndrome BP decoder of the wireless device may input the LLR magnitudes 305 and the syndromes 310 into a tanner graph, such as the tanner graph 300 to perform message passing (e.g., BP). The syndrome BP decoder may be associated with an FEC code (e.g., an LDPC code) used to generate the encoded bits.

The tanner graph 300 may include a set of variable nodes 315 (e.g., a variable node 315-a, a variable node 315-b, a variable node 315-c, and so on through a variable node 315-n) and a set of check nodes 320 (e.g., a check node 320-a, a check node 320-b, and so on through a check node 320-m). The wireless device may input each LLR magnitude 305 into a respective variable node 315 and each syndrome 310 into a respective check node 320. Each check node 320 may comprise a parity check condition that may be satisfied by associated variable nodes 315. For example, as illustrated with reference to the tanner graph 300, a value of the variable node 315-a, the variable node 315-b, and the variable node 315-c may sum to the value of the check node 320-a.

The tanner graph 300 may output an error vector e that satisfies s=Hr=He. A codeword c (e.g., a set of decoded bits) may be obtained by computing c=r+e in a binary field. The syndrome BP decoder may have a same performance as another decoder (e.g., a conventional BP decoder). Although the soft-syndrome BP decoding is illustrated with reference to the tanner graph 300, in some examples, one or more other tanner graphs may be used by an FEC component to generate an error vector.

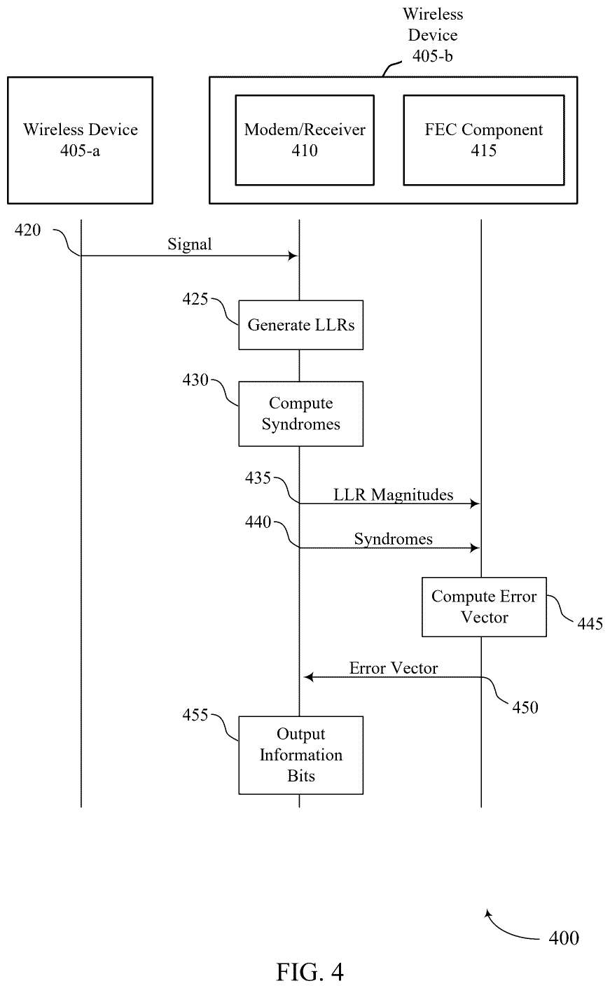

FIG. 4 shows an example of a process flow 400 that supports decoding a signal based on soft syndrome decoding techniques in accordance with one or more aspects of the present disclosure. The process flow 400 may implement or may be implemented by aspects of the wireless communications system 100, the wireless communication system 200, or the tanner graph 300. For example, the wireless communications system 200 may be implemented by a wireless device 405-a and a wireless device 405-b, which may be examples of a UE 115 or a network entity 105 as described with reference to FIG. 1.

In the following description of the process flow 400, the operations between the wireless device 405-a and the wireless device 405-b may occur in a different order than the example order shown and, in some examples, may be performed by one or more different devices other than those shown as examples. Some operations also may be omitted from the process flow 400, and other operations may be added to the process flow 400. Further, although some operations or signaling may be shown to occur at different times for discussion purposes, these operations may actually occur at the same time.

At 420, the wireless device 405-b may receive a signal from the wireless device 405-a (e.g., at a modem/receiver 410 of the wireless device 405-a). The signal may include a set of encoded bits, including one or more encoded information bits. In some examples, the set of encoded bits may include one or more punctured bits.

At 425, the modem/receiver 410 may generate a plurality of LLRs of the encoded bits. The plurality of LLRs may include a sign vector associated with the LLRs and a plurality of LLR magnitudes associated with the LLRs. At 430, the modem/receiver may compute a plurality of syndromes (e.g., a syndrome vector) using the sign vector and a parity check matrix. For example, the modem/receiver may obtain a hard decision vector using the sign vector, and may multiply the hard decision vector by the parity check matrix to obtain the syndrome vector.

In some examples, the modem/receiver 410 may generate the sign vector based on the one or more punctured bits. For example, the modem/receiver 410 may set values of the sign vector corresponding to the punctured bits to a predefined value (e.g., 0). Additionally, or alternatively, the modem/receiver 410 may generate (e.g., randomly generate) values of the sign vector corresponding to the punctured bits using a random value generator.

At 435 and 440, the modem/receiver 410 may output the LLR magnitudes and the syndrome vector, respectively, to an FEC component 415 that is capable of performing decoding. For example, the FEC component 415 may include an FEC decoder associated with an FEC code (e.g., an LDPC code) used by the wireless device 405-a to encode the signal. A quantity of bits used to output the LLR magnitudes and the syndrome vector to the FEC component 415 may be less than a product of a code length N associated with the signal and a quantization level B associated with the signal. The quantity of bits (per information bit) may be based on a code rate K/N of the signal.

At 445, the FEC component 415 may compute an error vector based on the syndrome vector and the LLR magnitudes. For example, the FEC component 415 may perform belief propagation on a tanner graph. The tanner graph may include a plurality of check nodes into which the FEC component 415 may input the syndromes and a plurality of variable nodes into which the FEC component 415 may input the LLR magnitudes. The tanner graph may accordingly compute the error vector. At 450, the FEC component may output the error vector (e.g., or a portion of the error vector corresponding to the information bits) to the modem/receiver 410.

At 455, the modem/receiver 410 may generate (e.g., output) a vector of information bits (e.g., a codeword vector). For example, the modem/receiver may compute the information bits based on calculating a sum of the error vector and the sign vector.

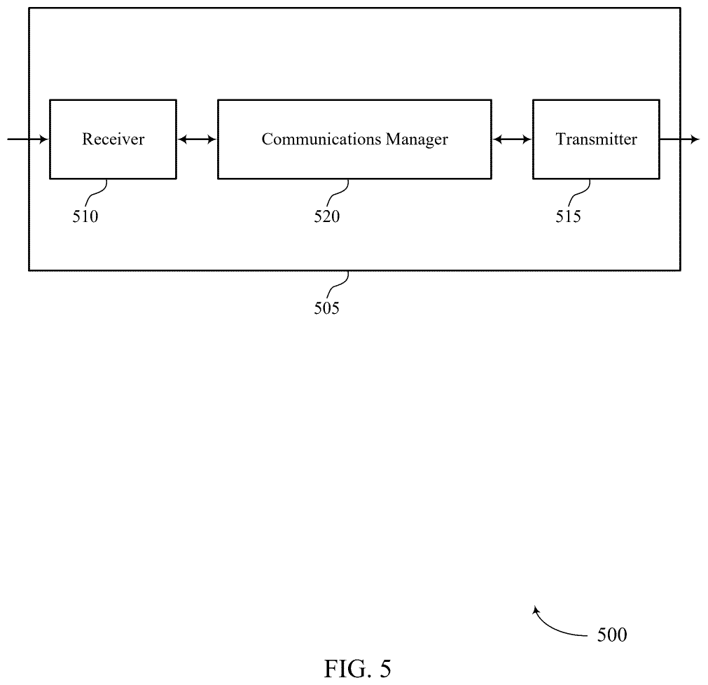

FIG. 5 shows a block diagram 500 of a device 505 that supports decoding a signal based on soft syndrome decoding techniques in accordance with one or more aspects of the present disclosure. The device 505 may be an example of aspects of a network entity 105 as described herein. The device 505 may include a receiver 510, a transmitter 515, and a communications manager 520. The device 505, or one or more components of the device 505 (e.g., the receiver 510, the transmitter 515, the communications manager 520), may include at least one processor, which may be coupled with at least one memory, to, individually or collectively, support or enable the described techniques. Each of these components may be in communication with one another (e.g., via one or more buses).

The receiver 510 may provide a means for obtaining (e.g., receiving, determining, identifying) information such as user data, control information, or any combination thereof (e.g., I/Q samples, symbols, packets, protocol data units, service data units) associated with various channels (e.g., control channels, data channels, information channels, channels associated with a protocol stack). Information may be passed on to other components of the device 505. In some examples, the receiver 510 may support obtaining information by receiving signals via one or more antennas. Additionally, or alternatively, the receiver 510 may support obtaining information by receiving signals via one or more wired (e.g., electrical, fiber optic) interfaces, wireless interfaces, or any combination thereof.

The transmitter 515 may provide a means for outputting (e.g., transmitting, providing, conveying, sending) information generated by other components of the device 505. For example, the transmitter 515 may output information such as user data, control information, or any combination thereof (e.g., I/Q samples, symbols, packets, protocol data units, service data units) associated with various channels (e.g., control channels, data channels, information channels, channels associated with a protocol stack). In some examples, the transmitter 515 may support outputting information by transmitting signals via one or more antennas. Additionally, or alternatively, the transmitter 515 may support outputting information by transmitting signals via one or more wired (e.g., electrical, fiber optic) interfaces, wireless interfaces, or any combination thereof. In some examples, the transmitter 515 and the receiver 510 may be co-located in a transceiver, which may include or be coupled with a modem.

The communications manager 520, the receiver 510, the transmitter 515, or various combinations or components thereof may be examples of means for performing various aspects of decoding a signal based on soft syndrome decoding techniques as described herein. For example, the communications manager 520, the receiver 510, the transmitter 515, or various combinations or components thereof may be capable of performing one or more of the functions described herein.

In some examples, the communications manager 520, the receiver 510, the transmitter 515, or various combinations or components thereof may be implemented in hardware (e.g., in communications management circuitry). The hardware may include at least one of a processor, a digital signal processor (DSP), a central processing unit (CPU), a graphics processing unit (GPU), a neural processing unit (NPU), an ASIC, an FPGA or other programmable logic device, a microcontroller, discrete gate or transistor logic, discrete hardware components, or any combination thereof configured as or otherwise supporting, individually or collectively, a means for performing the functions described in the present disclosure. In some examples, at least one processor and at least one memory coupled with the at least one processor may be configured to perform one or more of the functions described herein (e.g., by one or more processors, individually or collectively, executing instructions stored in the at least one memory).

Additionally, or alternatively, the communications manager 520, the receiver 510, the transmitter 515, or various combinations or components thereof may be implemented in code (e.g., as communications management software) executed by at least one processor (e.g., referred to as a processor-executable code). If implemented in code executed by at least one processor, the functions of the communications manager 520, the receiver 510, the transmitter 515, or various combinations or components thereof may be performed by a general-purpose processor, a DSP, a CPU, a GPU, a NPU, an ASIC, an FPGA, a microcontroller, or any combination of these or other programmable logic devices (e.g., configured as or otherwise supporting, individually or collectively, a means for performing the functions described in the present disclosure).

In some examples, the communications manager 520 may be configured to perform various operations (e.g., receiving, obtaining, monitoring, outputting, transmitting) using or otherwise in cooperation with the receiver 510, the transmitter 515, or both. For example, the communications manager 520 may receive information from the receiver 510, send information to the transmitter 515, or be integrated in combination with the receiver 510, the transmitter 515, or both to obtain information, output information, or perform various other operations as described herein.

The communications manager 520 may support wireless communications in accordance with examples as disclosed herein. For example, the communications manager 520 is capable of, configured to, or operable to support a means for receiving a signal including a set of multiple encoded bits. The communications manager 520 is capable of, configured to, or operable to support a means for generating, from the signal, a set of multiple LLRs of the set of multiple encoded bits, where the set of multiple LLRs include a sign vector associated with the set of multiple LLRs and a set of multiple LLR magnitudes associated with the set of multiple LLRs. The communications manager 520 is capable of, configured to, or operable to support a means for computing a set of multiple syndromes based on the sign vector. The communications manager 520 is capable of, configured to, or operable to support a means for computing an error vector based on the set of multiple syndromes and the set of multiple LLR magnitudes. The communications manager 520 is capable of, configured to, or operable to support a means for outputting a set of multiple information bits based on the error vector and the sign vector.

Additionally, or alternatively, the communications manager 520 may support wireless communications in accordance with examples as disclosed herein. For example, the communications manager 520 is capable of, configured to, or operable to support a means for receiving a signal including a set of multiple encoded bits. The communications manager 520 is capable of, configured to, or operable to support a means for generating, from the signal, a set of multiple LLRs of the set of multiple encoded bits, where the set of multiple LLRs include a sign vector associated with the set of multiple LLRs and a set of multiple LLR magnitudes associated with the set of multiple LLRs. The communications manager 520 is capable of, configured to, or operable to support a means for computing a set of multiple syndromes based on the sign vector. The communications manager 520 is capable of, configured to, or operable to support a means for outputting the set of multiple syndromes and the set of multiple LLR magnitudes. The communications manager 520 is capable of, configured to, or operable to support a means for obtaining an error vector based on the set of multiple syndromes and the set of multiple LLR magnitudes. The communications manager 520 is capable of, configured to, or operable to support a means for outputting a set of multiple information bits based on the error vector and the sign vector.

Additionally, or alternatively, the communications manager 520 may support wireless communications in accordance with examples as disclosed herein. For example, the communications manager 520 is capable of, configured to, or operable to support a means for obtaining a set of multiple syndromes associated with a signal and a set of multiple LLR magnitudes that correspond to a set of multiple LLRs associated with the signal, the signal including a set of multiple encoded bits, where the set of multiple LLRs and the set of multiple syndromes are associated with the set of multiple encoded bits. The communications manager 520 is capable of, configured to, or operable to support a means for computing an error vector based on the set of multiple syndromes and the set of multiple LLR magnitudes. The communications manager 520 is capable of, configured to, or operable to support a means for outputting the error vector.

By including or configuring the communications manager 520 in accordance with examples as described herein, the device 505 (e.g., at least one processor controlling or otherwise coupled with the receiver 510, the transmitter 515, the communications manager 520, or a combination thereof) may support techniques for syndrome-based decoding, which may enable more efficient utilization of communication resources related to reduced overhead.

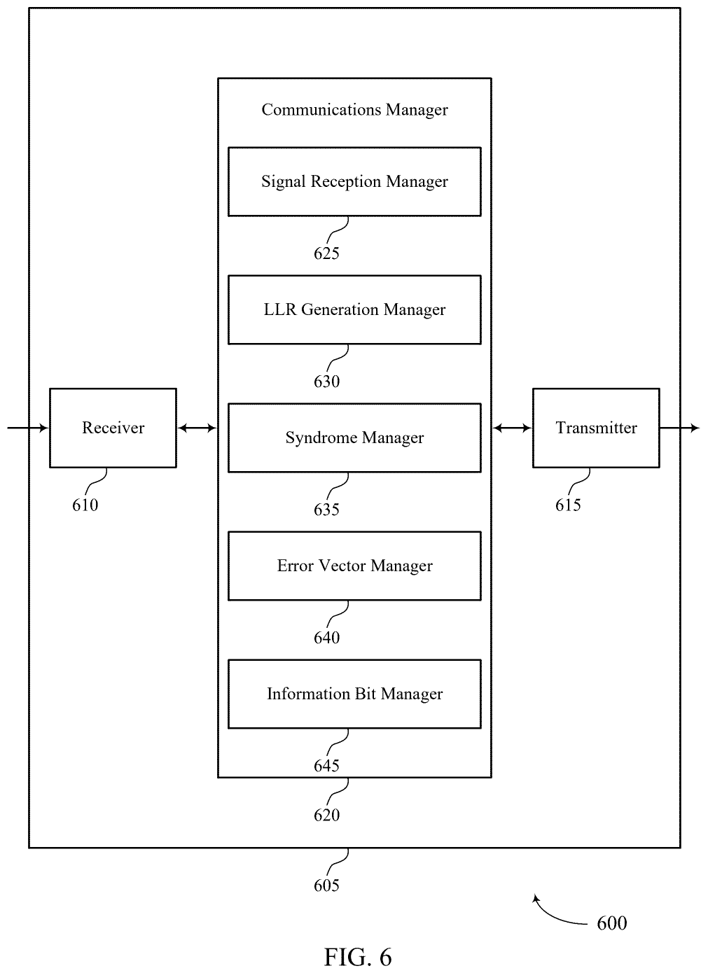

FIG. 6 shows a block diagram 600 of a device 605 that supports decoding a signal based on soft syndrome decoding techniques in accordance with one or more aspects of the present disclosure. The device 605 may be an example of aspects of a device 505 or a network entity 105 as described herein. The device 605 may include a receiver 610, a transmitter 615, and a communications manager 620. The device 605, or one or more components of the device 605 (e.g., the receiver 610, the transmitter 615, the communications manager 620), may include at least one processor, which may be coupled with at least one memory, to support the described techniques. Each of these components may be in communication with one another (e.g., via one or more buses).

The receiver 610 may provide a means for obtaining (e.g., receiving, determining, identifying) information such as user data, control information, or any combination thereof (e.g., I/Q samples, symbols, packets, protocol data units, service data units) associated with various channels (e.g., control channels, data channels, information channels, channels associated with a protocol stack). Information may be passed on to other components of the device 605. In some examples, the receiver 610 may support obtaining information by receiving signals via one or more antennas. Additionally, or alternatively, the receiver 610 may support obtaining information by receiving signals via one or more wired (e.g., electrical, fiber optic) interfaces, wireless interfaces, or any combination thereof.

The transmitter 615 may provide a means for outputting (e.g., transmitting, providing, conveying, sending) information generated by other components of the device 605. For example, the transmitter 615 may output information such as user data, control information, or any combination thereof (e.g., I/Q samples, symbols, packets, protocol data units, service data units) associated with various channels (e.g., control channels, data channels, information channels, channels associated with a protocol stack). In some examples, the transmitter 615 may support outputting information by transmitting signals via one or more antennas. Additionally, or alternatively, the transmitter 615 may support outputting information by transmitting signals via one or more wired (e.g., electrical, fiber optic) interfaces, wireless interfaces, or any combination thereof. In some examples, the transmitter 615 and the receiver 610 may be co-located in a transceiver, which may include or be coupled with a modem.

The device 605, or various components thereof, may be an example of means for performing various aspects of decoding a signal based on soft syndrome decoding techniques as described herein. For example, the communications manager 620 may include a signal reception manager 625, an LLR generation manager 630, a syndrome manager 635, an error vector manager 640, an information bit manager 645, or any combination thereof. The communications manager 620 may be an example of aspects of a communications manager 520 as described herein. In some examples, the communications manager 620, or various components thereof, may be configured to perform various operations (e.g., receiving, obtaining, monitoring, outputting, transmitting) using or otherwise in cooperation with the receiver 610, the transmitter 615, or both. For example, the communications manager 620 may receive information from the receiver 610, send information to the transmitter 615, or be integrated in combination with the receiver 610, the transmitter 615, or both to obtain information, output information, or perform various other operations as described herein.

The communications manager 620 may support wireless communications in accordance with examples as disclosed herein. The signal reception manager 625 is capable of, configured to, or operable to support a means for receiving a signal including a set of multiple encoded bits. The LLR generation manager 630 is capable of, configured to, or operable to support a means for generating, from the signal, a set of multiple LLRs of the set of multiple encoded bits, where the set of multiple LLRs include a sign vector associated with the set of multiple LLRs and a set of multiple LLR magnitudes associated with the set of multiple LLRs. The syndrome manager 635 is capable of, configured to, or operable to support a means for computing a set of multiple syndromes based on the sign vector. The error vector manager 640 is capable of, configured to, or operable to support a means for computing an error vector based on the set of multiple syndromes and the set of multiple LLR magnitudes. The information bit manager 645 is capable of, configured to, or operable to support a means for outputting a set of multiple information bits based on the error vector and the sign vector.

Additionally, or alternatively, the communications manager 620 may support wireless communications in accordance with examples as disclosed herein. The signal reception manager 625 is capable of, configured to, or operable to support a means for receiving a signal including a set of multiple encoded bits. The LLR generation manager 630 is capable of, configured to, or operable to support a means for generating, from the signal, a set of multiple LLRs of the set of multiple encoded bits, where the set of multiple LLRs include a sign vector associated with the set of multiple LLRs and a set of multiple LLR magnitudes associated with the set of multiple LLRs. The syndrome manager 635 is capable of, configured to, or operable to support a means for computing a set of multiple syndromes based on the sign vector. The syndrome manager 635 is capable of, configured to, or operable to support a means for outputting the set of multiple syndromes and the set of multiple LLR magnitudes. The error vector manager 640 is capable of, configured to, or operable to support a means for obtaining an error vector based on the set of multiple syndromes and the set of multiple LLR magnitudes. The information bit manager 645 is capable of, configured to, or operable to support a means for outputting a set of multiple information bits based on the error vector and the sign vector.

Additionally, or alternatively, the communications manager 620 may support wireless communications in accordance with examples as disclosed herein. The syndrome manager 635 is capable of, configured to, or operable to support a means for obtaining a set of multiple syndromes associated with a signal and a set of multiple LLR magnitudes that correspond to a set of multiple LLRs associated with the signal, the signal including a set of multiple encoded bits, where the set of multiple LLRs and the set of multiple syndromes are associated with the set of multiple encoded bits. The error vector manager 640 is capable of, configured to, or operable to support a means for computing an error vector based on the set of multiple syndromes and the set of multiple LLR magnitudes. The error vector manager 640 is capable of, configured to, or operable to support a means for outputting the error vector.

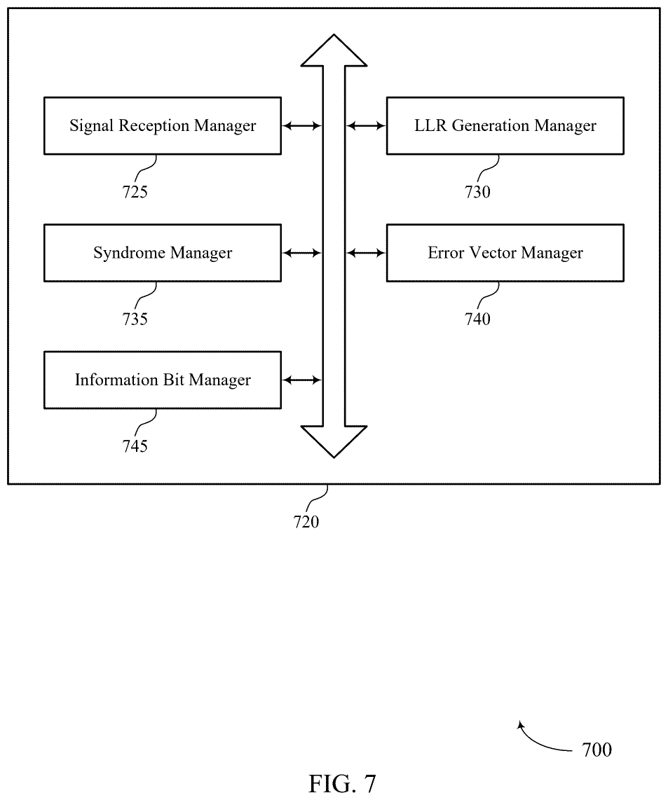

FIG. 7 shows a block diagram 700 of a communications manager 720 that supports decoding a signal based on soft syndrome decoding techniques in accordance with one or more aspects of the present disclosure. The communications manager 720 may be an example of aspects of a communications manager 520, a communications manager 620, or both, as described herein. The communications manager 720, or various components thereof, may be an example of means for performing various aspects of decoding a signal based on soft syndrome decoding techniques as described herein. For example, the communications manager 720 may include a signal reception manager 725, an LLR generation manager 730, a syndrome manager 735, an error vector manager 740, an information bit manager 745, or any combination thereof. Each of these components, or components or subcomponents thereof (e.g., one or more processors, one or more memories), may communicate, directly or indirectly, with one another (e.g., via one or more buses). The communications may include communications within a protocol layer of a protocol stack, communications associated with a logical channel of a protocol stack (e.g., between protocol layers of a protocol stack, within a device, component, or virtualized component associated with a network entity 105, between devices, components, or virtualized components associated with a network entity 105), or any combination thereof.

The communications manager 720 may support wireless communications in accordance with examples as disclosed herein. The signal reception manager 725 is capable of, configured to, or operable to support a means for receiving a signal including a set of multiple encoded bits. The LLR generation manager 730 is capable of, configured to, or operable to support a means for generating, from the signal, a set of multiple LLRs of the set of multiple encoded bits, where the set of multiple LLRs include a sign vector associated with the set of multiple LLRs and a set of multiple LLR magnitudes associated with the set of multiple LLRs. The syndrome manager 735 is capable of, configured to, or operable to support a means for computing a set of multiple syndromes based on the sign vector. The error vector manager 740 is capable of, configured to, or operable to support a means for computing an error vector based on the set of multiple syndromes and the set of multiple LLR magnitudes. The information bit manager 745 is capable of, configured to, or operable to support a means for outputting a set of multiple information bits based on the error vector and the sign vector.

In some examples, the error vector manager 740 is capable of, configured to, or operable to support a means for outputting, to a decoder, the set of multiple syndromes and the set of multiple LLR magnitudes, where computing the error vector includes computing the error vector based on the set of multiple syndromes and the set of multiple LLR magnitudes. In some examples, the error vector manager 740 is capable of, configured to, or operable to support a means for computing, by the decoder, the error vector based on the set of multiple syndromes and the set of multiple LLR magnitudes.

In some examples, to support outputting the set of multiple syndromes and the set of multiple LLR magnitudes, the error vector manager 740 is capable of, configured to, or operable to support a means for outputting a quantity of bits that is less than a product of a code length associated with the signal and a quantization level associated with the signal, where the quantity of bits is based on a coding rate of the signal.

In some examples, the decoder is a FEC decoder associated with a FEC code used to generate the set of multiple encoded bits.

In some examples, the error vector manager 740 is capable of, configured to, or operable to support a means for outputting, by a decoder to a modem, the error vector, where outputting the set of multiple information bits further includes outputting the set of multiple information bits based on the error vector. In some examples, the information bit manager 745 is capable of, configured to, or operable to support a means for outputting, by the modem, the set of multiple information bits based on the error vector.

In some examples, to support computing the error vector, the error vector manager 740 is capable of, configured to, or operable to support a means for performing belief propagation on a tanner graph, where the tanner graph includes a set of multiple check nodes each corresponding to one of the set of multiple syndromes and a set of multiple variable nodes each corresponding to one of the set of multiple LLR magnitudes.

In some examples, to support outputting the set of multiple information bits, the information bit manager 745 is capable of, configured to, or operable to support a means for computing a codeword vector, where the codeword vector includes a sum of the error vector and the sign vector.

In some examples, to support receiving the signal including the set of multiple encoded bits, the signal reception manager 725 is capable of, configured to, or operable to support a means for receiving the set of multiple encoded bits including one or more punctured bits, where the sign vector is generated based on the one or more punctured bits.

In some examples, the LLR generation manager 730 is capable of, configured to, or operable to support a means for generating, using a random value generator, one or more sign values corresponding to each of the one or more punctured bits.

In some examples, the LLR generation manager 730 is capable of, configured to, or operable to support a means for generating the sign vector, where one or more values of the sign vector corresponding to the one or more punctured bits are equal to a predefined value.

Additionally, or alternatively, the communications manager 720 may support wireless communications in accordance with examples as disclosed herein. In some examples, the signal reception manager 725 is capable of, configured to, or operable to support a means for receiving a signal including a set of multiple encoded bits. In some examples, the LLR generation manager 730 is capable of, configured to, or operable to support a means for generating, from the signal, a set of multiple LLRs of the set of multiple encoded bits, where the set of multiple LLRs include a sign vector associated with the set of multiple LLRs and a set of multiple LLR magnitudes associated with the set of multiple LLRs. In some examples, the syndrome manager 735 is capable of, configured to, or operable to support a means for computing a set of multiple syndromes based on the sign vector. In some examples, the syndrome manager 735 is capable of, configured to, or operable to support a means for outputting the set of multiple syndromes and the set of multiple LLR magnitudes. In some examples, the error vector manager 740 is capable of, configured to, or operable to support a means for obtaining an error vector based on the set of multiple syndromes and the set of multiple LLR magnitudes. In some examples, the information bit manager 745 is capable of, configured to, or operable to support a means for outputting a set of multiple information bits based on the error vector and the sign vector.

In some examples, to support outputting the set of multiple information bits, the information bit manager 745 is capable of, configured to, or operable to support a means for computing a codeword vector, where the codeword vector includes a sum of the error vector and the sign vector.

In some examples, to support receiving the signal including the set of multiple encoded bits, the signal reception manager 725 is capable of, configured to, or operable to support a means for receiving the set of multiple encoded bits including one or more punctured bits, where generating the sign vector is based on the one or more punctured bits.

In some examples, the LLR generation manager 730 is capable of, configured to, or operable to support a means for generating, using a random value generator, one or more sign values corresponding to each of the one or more punctured bits.

In some examples, the LLR generation manager 730 is capable of, configured to, or operable to support a means for generating the sign vector, where one or more values of the sign vector corresponding to the one or more punctured bits are equal to 0.

In some examples, to support outputting the set of multiple syndromes and the set of multiple LLR magnitudes, the syndrome manager 735 is capable of, configured to, or operable to support a means for outputting a quantity of bits that is less than a product of a code length associated with the signal and a quantization level associated with the signal, where the quantity of bits is based on a coding rate of the signal.

Additionally, or alternatively, the communications manager 720 may support wireless communications in accordance with examples as disclosed herein. In some examples, the syndrome manager 735 is capable of, configured to, or operable to support a means for obtaining a set of multiple syndromes associated with a signal and a set of multiple LLR magnitudes that correspond to a set of multiple LLRs associated with the signal, the signal including a set of multiple encoded bits, where the set of multiple LLRs and the set of multiple syndromes are associated with the set of multiple encoded bits. In some examples, the error vector manager 740 is capable of, configured to, or operable to support a means for computing an error vector based on the set of multiple syndromes and the set of multiple LLR magnitudes. In some examples, the error vector manager 740 is capable of, configured to, or operable to support a means for outputting the error vector.

In some examples, to support computing the error vector, the error vector manager 740 is capable of, configured to, or operable to support a means for performing belief propagation on a tanner graph, where the tanner graph includes a set of multiple check nodes each corresponding to one of the set of multiple syndromes and a set of multiple variable nodes each corresponding to one of the set of multiple LLR magnitudes.

In some examples, to support obtaining the set of multiple syndromes and the set of multiple LLR magnitudes, the syndrome manager 735 is capable of, configured to, or operable to support a means for obtaining a quantity of bits that is less than a product of a code length associated with the signal and a quantization level associated with the signal, where the quantity of bits is based on a coding rate of the signal.

In some examples, the decoder is a FEC decoder associated with a FEC code used to generate the set of multiple encoded bits.

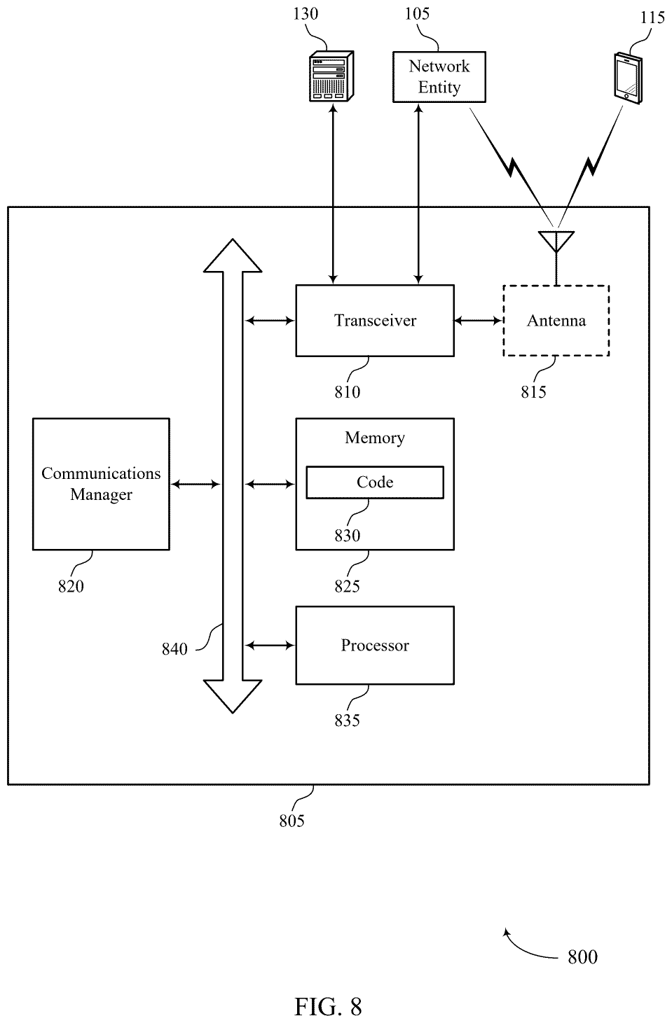

FIG. 8 shows a diagram of a system 800 including a device 805 that supports decoding a signal based on soft syndrome decoding techniques in accordance with one or more aspects of the present disclosure. The device 805 may be an example of or include components of a device 505, a device 605, or a network entity 105 as described herein. The device 805 may communicate with other network devices or network equipment such as one or more of the network entities 105, UEs 115, or any combination thereof. The communications may include communications over one or more wired interfaces, over one or more wireless interfaces, or any combination thereof. The device 805 may include components that support outputting and obtaining communications, such as a communications manager 820, a transceiver 810, one or more antennas 815, at least one memory 825, code 830, and at least one processor 835. These components may be in electronic communication or otherwise coupled (e.g., operatively, communicatively, functionally, electronically, electrically) via one or more buses (e.g., a bus 840).

The transceiver 810 may support bi-directional communications via wired links, wireless links, or both as described herein. In some examples, the transceiver 810 may include a wired transceiver and may communicate bi-directionally with another wired transceiver. Additionally, or alternatively, in some examples, the transceiver 810 may include a wireless transceiver and may communicate bi-directionally with another wireless transceiver. In some examples, the device 805 may include one or more antennas 815, which may be capable of transmitting or receiving wireless transmissions (e.g., concurrently). The transceiver 810 may also include a modem to modulate signals, to provide the modulated signals for transmission (e.g., by one or more antennas 815, by a wired transmitter), to receive modulated signals (e.g., from one or more antennas 815, from a wired receiver), and to demodulate signals. In some implementations, the transceiver 810 may include one or more interfaces, such as one or more interfaces coupled with the one or more antennas 815 that are configured to support various receiving or obtaining operations, or one or more interfaces coupled with the one or more antennas 815 that are configured to support various transmitting or outputting operations, or a combination thereof. In some implementations, the transceiver 810 may include or be configured for coupling with one or more processors or one or more memory components that are operable to perform or support operations based on received or obtained information or signals, or to generate information or other signals for transmission or other outputting, or any combination thereof. In some implementations, the transceiver 810, or the transceiver 810 and the one or more antennas 815, or the transceiver 810 and the one or more antennas 815 and one or more processors or one or more memory components (e.g., the at least one processor 835, the at least one memory 825, or both), may be included in a chip or chip assembly that is installed in the device 805. In some examples, the transceiver 810 may be operable to support communications via one or more communications links (e.g., communication link(s) 125, backhaul communication link(s) 120, a midhaul communication link 162, a fronthaul communication link 168).

The at least one memory 825 may include RAM, ROM, or any combination thereof. The at least one memory 825 may store computer-readable, computer-executable, or processor-executable code, such as the code 830. The code 830 may include instructions that, when executed by one or more of the at least one processor 835, cause the device 805 to perform various functions described herein. The code 830 may be stored in a non-transitory computer-readable medium such as system memory or another type of memory. In some cases, the code 830 may not be directly executable by a processor of the at least one processor 835 but may cause a computer (e.g., when compiled and executed) to perform functions described herein. In some cases, the at least one memory 825 may include, among other things, a BIOS which may control basic hardware or software operation such as the interaction with peripheral components or devices. In some examples, the at least one processor 835 may include multiple processors and the at least one memory 825 may include multiple memories. One or more of the multiple processors may be coupled with one or more of the multiple memories which may, individually or collectively, be configured to perform various functions herein (for example, as part of a processing system).

The at least one processor 835 may include one or more intelligent hardware devices (e.g., one or more general-purpose processors, one or more DSPs, one or more CPUs, GPUs, one or more NPUs (also referred to as neural network processors or deep learning processors (DLPs)), one or more microcontrollers, one or more ASICs, one or more FPGAs, one or more programmable logic devices, discrete gate or transistor logic, one or more discrete hardware components, or any combination thereof). In some cases, the at least one processor 835 may be configured to operate a memory array using a memory controller. In some other cases, a memory controller may be integrated into one or more of the at least one processor 835. The at least one processor 835 may be configured to execute computer-readable instructions stored in a memory (e.g., one or more of the at least one memory 825) to cause the device 805 to perform various functions (e.g., functions or tasks supporting decoding a signal based on soft syndrome decoding techniques). For example, the device 805 or a component of the device 805 may include at least one processor 835 and at least one memory 825 coupled with one or more of the at least one processor 835, the at least one processor 835 and the at least one memory 825 configured to perform various functions described herein. The at least one processor 835 may be an example of a cloud-computing platform (e.g., one or more physical nodes and supporting software such as operating systems, virtual machines, or container instances) that may host the functions (e.g., by executing code 830) to perform the functions of the device 805. The at least one processor 835 may be any one or more suitable processors capable of executing scripts or instructions of one or more software programs stored in the device 805 (such as within one or more of the at least one memory 825).

In some examples, the at least one processor 835 may include multiple processors and the at least one memory 825 may include multiple memories. One or more of the multiple processors may be coupled with one or more of the multiple memories, which may, individually or collectively, be configured to perform various functions herein. In some examples, the at least one processor 835 may be a component of a processing system, which may refer to a system (such as a series) of machines, circuitry (including, for example, one or both of processor circuitry (which may include the at least one processor 835) and memory circuitry (which may include the at least one memory 825)), or components, that receives or obtains inputs and processes the inputs to produce, generate, or obtain a set of outputs. The processing system may be configured to perform one or more of the functions described herein. For example, the at least one processor 835 or a processing system including the at least one processor 835 may be configured to, configurable to, or operable to cause the device 805 to perform one or more of the functions described herein. Further, as described herein, being “configured to,” being “configurable to,” and being “operable to” may be used interchangeably and may be associated with a capability, when executing code stored in the at least one memory 825 or otherwise, to perform one or more of the functions described herein.

In some examples, a bus 840 may support communications of (e.g., within) a protocol layer of a protocol stack. In some examples, a bus 840 may support communications associated with a logical channel of a protocol stack (e.g., between protocol layers of a protocol stack), which may include communications performed within a component of the device 805, or between different components of the device 805 that may be co-located or located in different locations (e.g., where the device 805 may refer to a system in which one or more of the communications manager 820, the transceiver 810, the at least one memory 825, the code 830, and the at least one processor 835 may be located in one of the different components or divided between different components).

In some examples, the communications manager 820 may manage aspects of communications with a core network 130 (e.g., via one or more wired or wireless backhaul links). For example, the communications manager 820 may manage the transfer of data communications for client devices, such as one or more UEs 115. In some examples, the communications manager 820 may manage communications with one or more other network entities 105, and may include a controller or scheduler for controlling communications with UEs 115 (e.g., in cooperation with the one or more other network devices). In some examples, the communications manager 820 may support an X2 interface within an LTE/LTE-A wireless communications network technology to provide communication between network entities 105.

The communications manager 820 may support wireless communications in accordance with examples as disclosed herein. For example, the communications manager 820 is capable of, configured to, or operable to support a means for receiving a signal including a set of multiple encoded bits. The communications manager 820 is capable of, configured to, or operable to support a means for generating, from the signal, a set of multiple LLRs of the set of multiple encoded bits, where the set of multiple LLRs include a sign vector associated with the set of multiple LLRs and a set of multiple LLR magnitudes associated with the set of multiple LLRs. The communications manager 820 is capable of, configured to, or operable to support a means for computing a set of multiple syndromes based on the sign vector. The communications manager 820 is capable of, configured to, or operable to support a means for computing an error vector based on the set of multiple syndromes and the set of multiple LLR magnitudes. The communications manager 820 is capable of, configured to, or operable to support a means for outputting a set of multiple information bits based on the error vector and the sign vector.

Additionally, or alternatively, the communications manager 820 may support wireless communications in accordance with examples as disclosed herein. For example, the communications manager 820 is capable of, configured to, or operable to support a means for receiving a signal including a set of multiple encoded bits. The communications manager 820 is capable of, configured to, or operable to support a means for generating, from the signal, a set of multiple LLRs of the set of multiple encoded bits, where the set of multiple LLRs include a sign vector associated with the set of multiple LLRs and a set of multiple LLR magnitudes associated with the set of multiple LLRs. The communications manager 820 is capable of, configured to, or operable to support a means for computing a set of multiple syndromes based on the sign vector. The communications manager 820 is capable of, configured to, or operable to support a means for outputting the set of multiple syndromes and the set of multiple LLR magnitudes. The communications manager 820 is capable of, configured to, or operable to support a means for obtaining an error vector based on the set of multiple syndromes and the set of multiple LLR magnitudes. The communications manager 820 is capable of, configured to, or operable to support a means for outputting a set of multiple information bits based on the error vector and the sign vector.

Additionally, or alternatively, the communications manager 820 may support wireless communications in accordance with examples as disclosed herein. For example, the communications manager 820 is capable of, configured to, or operable to support a means for obtaining a set of multiple syndromes associated with a signal and a set of multiple LLR magnitudes that correspond to a set of multiple LLRs associated with the signal, the signal including a set of multiple encoded bits, where the set of multiple LLRs and the set of multiple syndromes are associated with the set of multiple encoded bits. The communications manager 820 is capable of, configured to, or operable to support a means for computing an error vector based on the set of multiple syndromes and the set of multiple LLR magnitudes. The communications manager 820 is capable of, configured to, or operable to support a means for outputting the error vector.

By including or configuring the communications manager 820 in accordance with examples as described herein, the device 805 may support techniques for syndrome-based decoding, which may enable more efficient utilization of communication resources, improved utilization of processing capability, and increased security.

In some examples, the communications manager 820 may be configured to perform various operations (e.g., receiving, obtaining, monitoring, outputting, transmitting) using or otherwise in cooperation with the transceiver 810, the one or more antennas 815 (e.g., where applicable), or any combination thereof. Although the communications manager 820 is illustrated as a separate component, in some examples, one or more functions described with reference to the communications manager 820 may be supported by or performed by the transceiver 810, one or more of the at least one processor 835, one or more of the at least one memory 825, the code 830, or any combination thereof (for example, by a processing system including at least a portion of the at least one processor 835, the at least one memory 825, the code 830, or any combination thereof). For example, the code 830 may include instructions executable by one or more of the at least one processor 835 to cause the device 805 to perform various aspects of decoding a signal based on soft syndrome decoding techniques as described herein, or the at least one processor 835 and the at least one memory 825 may be otherwise configured to, individually or collectively, perform or support such operations.

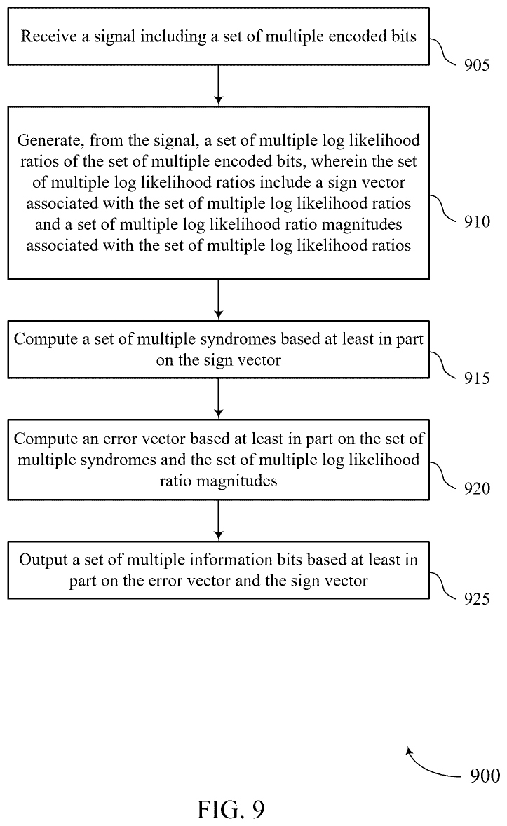

FIG. 9 shows a flowchart illustrating a method 900 that supports decoding a signal based on soft syndrome decoding techniques in accordance with one or more aspects of the present disclosure. The operations of the method 900 may be implemented by a network entity or its components as described herein. For example, the operations of the method 900 may be performed by a network entity as described with reference to FIGS. 1 through 8. In some examples, a network entity may execute a set of instructions to control the functional elements of the network entity to perform the described functions. Additionally, or alternatively, the network entity may perform aspects of the described functions using special-purpose hardware.

At 905, the method may include receiving a signal including a set of multiple encoded bits. The operations of 905 may be performed in accordance with examples as disclosed herein. In some examples, aspects of the operations of 905 may be performed by a communications manager 720 as described with reference to FIG. 7.

At 910, the method may include generating, from the signal, a set of multiple LLRs of the set of multiple encoded bits, wherein the set of multiple LLRs include a sign vector associated with the set of multiple LLRs and a set of multiple LLR magnitudes associated with the set of multiple LLRs. The operations of 910 may be performed in accordance with examples as disclosed herein. In some examples, aspects of the operations of 910 may be performed by a communications manager 720 as described with reference to FIG. 7.

At 915, the method may include computing a set of multiple syndromes based at least in part on the sign vector. The operations of 915 may be performed in accordance with examples as disclosed herein. In some examples, aspects of the operations of 915 may be performed by a communications manager 720 as described with reference to FIG. 7.

At 920, the method may include computing an error vector based at least in part on the set of multiple syndromes and the set of multiple LLR magnitudes. The operations of 920 may be performed in accordance with examples as disclosed herein.

In some examples, aspects of the operations of 920 may be performed by a communications manager 720 as described with reference to FIG. 7.

At 925, the method may include outputting a set of multiple information bits based at least in part on the error vector and the sign vector. The operations of 925 may be performed in accordance with examples as disclosed herein. In some examples, aspects of the operations of 925 may be performed by a communications manager 720 as described with reference to FIG. 7.

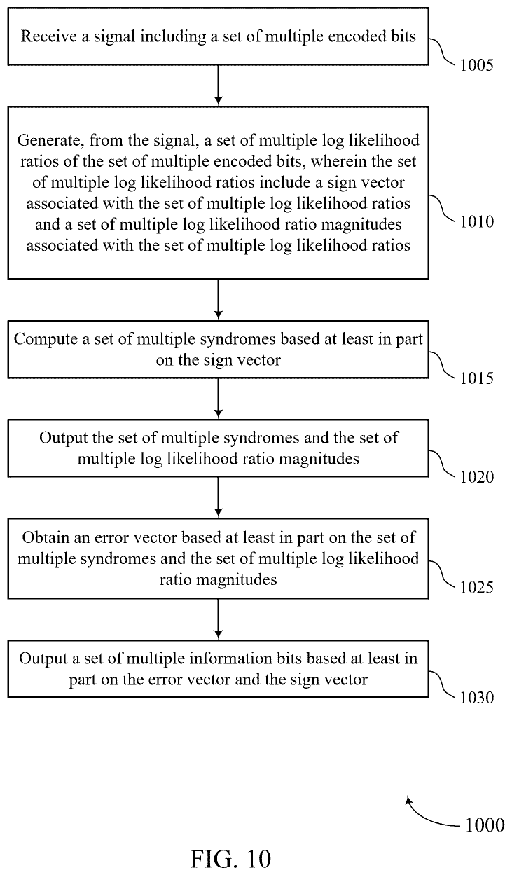

FIG. 10 shows a flowchart illustrating a method 1000 that supports decoding a signal based on soft syndrome decoding techniques in accordance with one or more aspects of the present disclosure. The operations of the method 1000 may be implemented by a network entity or its components as described herein. For example, the operations of the method 1000 may be performed by a network entity as described with reference to FIGS. 1 through 8. In some examples, a network entity may execute a set of instructions to control the functional elements of the network entity to perform the described functions. Additionally, or alternatively, the network entity may perform aspects of the described functions using special-purpose hardware.

At 1005, the method may include receiving a signal including a set of multiple encoded bits. The operations of 1005 may be performed in accordance with examples as disclosed herein. In some examples, aspects of the operations of 1005 may be performed by a communications manager 720 as described with reference to FIG. 7.

At 1010, the method may include generating, from the signal, a set of multiple LLRs of the set of multiple encoded bits, wherein the set of multiple LLRs include a sign vector associated with the set of multiple LLRs and a set of multiple LLR magnitudes associated with the set of multiple LLRs. The operations of 1010 may be performed in accordance with examples as disclosed herein. In some examples, aspects of the operations of 1010 may be performed by a communications manager 720 as described with reference to FIG. 7.

At 1015, the method may include computing a set of multiple syndromes based at least in part on the sign vector. The operations of 1015 may be performed in accordance with examples as disclosed herein. In some examples, aspects of the operations of 1015 may be performed by a communications manager 720 as described with reference to FIG. 7.

At 1020, the method may include outputting the set of multiple syndromes and the set of multiple LLR magnitudes. The operations of 1020 may be performed in accordance with examples as disclosed herein. In some examples, aspects of the operations of 1020 may be performed by a communications manager 720 as described with reference to FIG. 7.

At 1025, the method may include obtaining an error vector based at least in part on the set of multiple syndromes and the set of multiple LLR magnitudes. The operations of 1025 may be performed in accordance with examples as disclosed herein. In some examples, aspects of the operations of 1025 may be performed by a communications manager 720 as described with reference to FIG. 7.

At 1030, the method may include outputting a set of multiple information bits based at least in part on the error vector and the sign vector. The operations of 1030 may be performed in accordance with examples as disclosed herein. In some examples, aspects of the operations of 1030 may be performed by a communications manager 720 as described with reference to FIG. 7.

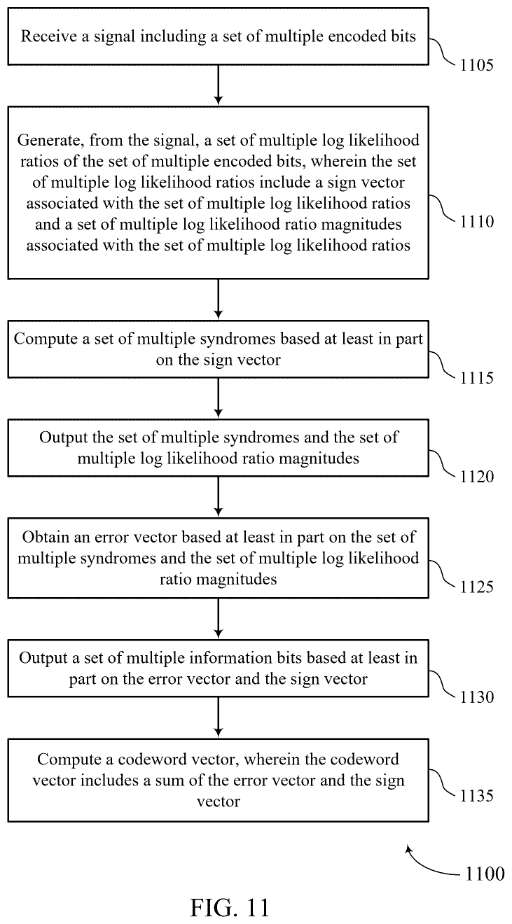

FIG. 11 shows a flowchart illustrating a method 1100 that supports decoding a signal based on soft syndrome decoding techniques in accordance with one or more aspects of the present disclosure. The operations of the method 1100 may be implemented by a network entity or its components as described herein. For example, the operations of the method 1100 may be performed by a network entity as described with reference to FIGS. 1 through 8. In some examples, a network entity may execute a set of instructions to control the functional elements of the network entity to perform the described functions. Additionally, or alternatively, the network entity may perform aspects of the described functions using special-purpose hardware.

At 1105, the method may include receiving a signal including a set of multiple encoded bits. The operations of 1105 may be performed in accordance with examples as disclosed herein. In some examples, aspects of the operations of 1105 may be performed by a communications manager 720 as described with reference to FIG. 7.

At 1110, the method may include generating, from the signal, a set of multiple LLRs of the set of multiple encoded bits, wherein the set of multiple LLRs include a sign vector associated with the set of multiple LLRs and a set of multiple LLR magnitudes associated with the set of multiple LLRs. The operations of 1110 may be performed in accordance with examples as disclosed herein. In some examples, aspects of the operations of 1110 may be performed by a communications manager 720 as described with reference to FIG. 7.

At 1115, the method may include computing a set of multiple syndromes based at least in part on the sign vector. The operations of 1115 may be performed in accordance with examples as disclosed herein. In some examples, aspects of the operations of 1115 may be performed by a communications manager 720 as described with reference to FIG. 7.

At 1120, the method may include outputting the set of multiple syndromes and the set of multiple LLR magnitudes. The operations of 1120 may be performed in accordance with examples as disclosed herein. In some examples, aspects of the operations of 1120 may be performed by a communications manager 720 as described with reference to FIG. 7.

At 1125, the method may include obtaining an error vector based at least in part on the set of multiple syndromes and the set of multiple LLR magnitudes. The operations of 1125 may be performed in accordance with examples as disclosed herein. In some examples, aspects of the operations of 1125 may be performed by a communications manager 720 as described with reference to FIG. 7.

At 1130, the method may include outputting a set of multiple information bits based at least in part on the error vector and the sign vector. The operations of 1130 may be performed in accordance with examples as disclosed herein. In some examples, aspects of the operations of 1130 may be performed by a communications manager 720 as described with reference to FIG. 7.

At 1135, the method may include computing a codeword vector, wherein the codeword vector includes a sum of the error vector and the sign vector. The operations of 1135 may be performed in accordance with examples as disclosed herein. In some examples, aspects of the operations of 1135 may be performed by a communications manager 720 as described with reference to FIG. 7.

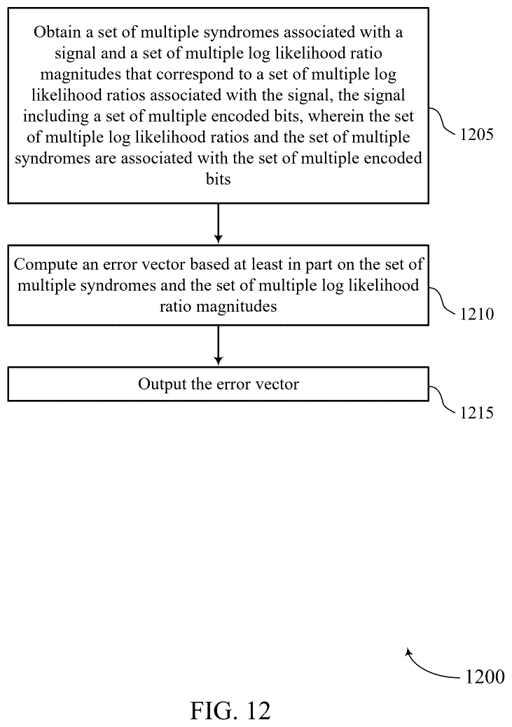

FIG. 12 shows a flowchart illustrating a method 1200 that supports decoding a signal based on soft syndrome decoding techniques in accordance with one or more aspects of the present disclosure. The operations of the method 1200 may be implemented by a network entity or its components as described herein. For example, the operations of the method 1200 may be performed by a network entity as described with reference to FIGS. 1 through 8. In some examples, a network entity may execute a set of instructions to control the functional elements of the network entity to perform the described functions. Additionally, or alternatively, the network entity may perform aspects of the described functions using special-purpose hardware.

At 1205, the method may include obtaining a set of multiple syndromes associated with a signal and a set of multiple LLR magnitudes that correspond to a set of multiple LLRs associated with the signal, the signal including a set of multiple encoded bits, wherein the set of multiple LLRs and the set of multiple syndromes are associated with the set of multiple encoded bits. The operations of 1205 may be performed in accordance with examples as disclosed herein. In some examples, aspects of the operations of 1205 may be performed by a communications manager 720 as described with reference to FIG. 7.

At 1210, the method may include computing an error vector based at least in part on the set of multiple syndromes and the set of multiple LLR magnitudes. The operations of 1210 may be performed in accordance with examples as disclosed herein. In some examples, aspects of the operations of 1210 may be performed by a communications manager 720 as described with reference to FIG. 7.

At 1215, the method may include outputting the error vector. The operations of 1215 may be performed in accordance with examples as disclosed herein. In some examples, aspects of the operations of 1215 may be performed by a communications manager 720 as described with reference to FIG. 7.

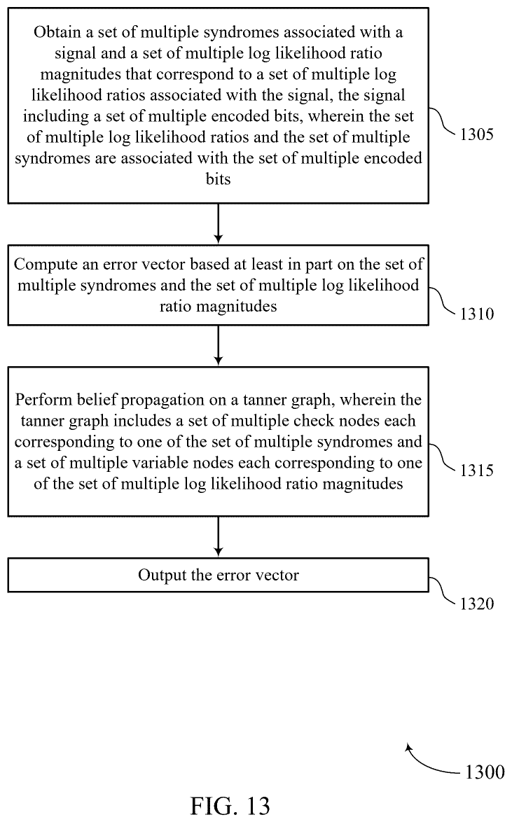

FIG. 13 shows a flowchart illustrating a method 1300 that supports decoding a signal based on soft syndrome decoding techniques in accordance with one or more aspects of the present disclosure. The operations of the method 1300 may be implemented by a network entity or its components as described herein. For example, the operations of the method 1300 may be performed by a network entity as described with reference to FIGS. 1 through 8. In some examples, a network entity may execute a set of instructions to control the functional elements of the network entity to perform the described functions. Additionally, or alternatively, the network entity may perform aspects of the described functions using special-purpose hardware.

At 1305, the method may include obtaining a set of multiple syndromes associated with a signal and a set of multiple LLR magnitudes that correspond to a set of multiple LLRs associated with the signal, the signal including a set of multiple encoded bits, wherein the set of multiple LLRs and the set of multiple syndromes are associated with the set of multiple encoded bits. The operations of 1305 may be performed in accordance with examples as disclosed herein. In some examples, aspects of the operations of 1305 may be performed by a communications manager 720 as described with reference to FIG. 7.

At 1310, the method may include computing an error vector based at least in part on the set of multiple syndromes and the set of multiple LLR magnitudes. The operations of 1310 may be performed in accordance with examples as disclosed herein. In some examples, aspects of the operations of 1310 may be performed by a communications manager 720 as described with reference to FIG. 7.

At 1315, the method may include performing belief propagation on a tanner graph, wherein the tanner graph includes a set of multiple check nodes each corresponding to one of the set of multiple syndromes and a set of multiple variable nodes each corresponding to one of the set of multiple LLR magnitudes. The operations of 1315 may be performed in accordance with examples as disclosed herein. In some examples, aspects of the operations of 1315 may be performed by a communications manager 720 as described with reference to FIG. 7.

At 1320, the method may include outputting the error vector. The operations of 1320 may be performed in accordance with examples as disclosed herein. In some examples, aspects of the operations of 1320 may be performed by a communications manager 720 as described with reference to FIG. 7.

The following provides an overview of aspects of the present disclosure:

Aspect 1: A method for wireless communications, comprising: receiving a signal comprising a plurality of encoded bits; generating, from the signal, a plurality of LLRs of the plurality of encoded bits, wherein the plurality of LLRs comprise a sign vector associated with the plurality of LLRs and a plurality of LLR magnitudes associated with the plurality of LLRs; computing a plurality of syndromes based at least in part on the sign vector; computing an error vector based at least in part on the plurality of syndromes and the plurality of LLR magnitudes; and outputting a plurality of information bits based at least in part on the error vector and the sign vector.

Aspect 2: The method of aspect 1, further comprising: outputting, to a decoder, the plurality of syndromes and the plurality of LLR magnitudes, wherein computing the error vector comprises: computing, by the decoder, the error vector based at least in part on the plurality of syndromes and the plurality of LLR magnitudes.

Aspect 3: The method of aspect 2, wherein outputting the plurality of syndromes and the plurality of LLR magnitudes comprises: outputting a quantity of bits that is less than a product of a code length associated with the signal and a quantization level associated with the signal, wherein the quantity of bits is based at least in part on a coding rate of the signal.

Aspect 4: The method of any of aspects 2 through 3, wherein the decoder is a FEC decoder associated with a FEC code used to generate the plurality of encoded bits.

Aspect 5: The method of any of aspects 1 through 4, further comprising: outputting, by a decoder to a modem, the error vector, wherein outputting the plurality of information bits further comprises: outputting, by the modem, the plurality of information bits based at least in part on the error vector.

Aspect 6: The method of any of aspects 1 through 5, wherein computing the error vector comprises: performing belief propagation on a tanner graph, wherein the tanner graph comprises a plurality of check nodes each corresponding to one of the plurality of syndromes and a plurality of variable nodes each corresponding to one of the plurality of LLR magnitudes.

Aspect 7: The method of any of aspects 1 through 6, wherein outputting the plurality of information bits comprises: computing a codeword vector, wherein the codeword vector comprises a sum of the error vector and the sign vector.

Aspect 8: The method of any of aspects 1 through 7, wherein receiving the signal comprising the plurality of encoded bits comprises: receiving the plurality of encoded bits comprising one or more punctured bits, wherein the sign vector is generated based at least in part on the one or more punctured bits.

Aspect 9: The method of aspect 8, further comprising: generating, using a random value generator, one or more sign values corresponding to each of the one or more punctured bits.

Aspect 10: The method of any of aspects 8 through 9, further comprising: generating the sign vector, wherein one or more values of the sign vector corresponding to the one or more punctured bits are equal to a predefined value.

Aspect 11: A method for wireless communications by a modem of a wireless device, comprising: receiving a signal comprising a plurality of encoded bits; generating, from the signal, a plurality of LLRs of the plurality of encoded bits, wherein the plurality of LLRs comprise a sign vector associated with the plurality of LLRs and a plurality of LLR magnitudes associated with the plurality of LLRs; computing a plurality of syndromes based at least in part on the sign vector; outputting the plurality of syndromes and the plurality of LLR magnitudes; obtaining an error vector based at least in part on the plurality of syndromes and the plurality of LLR magnitudes; and outputting a plurality of information bits based at least in part on the error vector and the sign vector.

Aspect 12: The method of aspect 11, wherein outputting the plurality of information bits comprises: computing a codeword vector, wherein the codeword vector comprises a sum of the error vector and the sign vector.

Aspect 13: The method of any of aspects 11 through 12, wherein receiving the signal comprising the plurality of encoded bits comprises: receiving the plurality of encoded bits comprising one or more punctured bits, wherein generating the sign vector is based at least in part on the one or more punctured bits.

Aspect 14: The method of aspect 13, further comprising: generating, using a random value generator, one or more sign values corresponding to each of the one or more punctured bits.

Aspect 15: The method of any of aspects 13 through 14, further comprising: generating the sign vector, wherein one or more values of the sign vector corresponding to the one or more punctured bits are equal to 0.

Aspect 16: The method of any of aspects 11 through 15, wherein outputting the plurality of syndromes and the plurality of LLR magnitudes comprises: outputting a quantity of bits that is less than a product of a code length associated with the signal and a quantization level associated with the signal, wherein the quantity of bits is based at least in part on a coding rate of the signal.

Aspect 17: A method for wireless communications by a decoder, comprising: obtaining a plurality of syndromes associated with a signal and a plurality of LLR magnitudes that correspond to a plurality of LLRs associated with the signal, the signal comprising a plurality of encoded bits, wherein the plurality of LLRs and the plurality of syndromes are associated with the plurality of encoded bits; computing an error vector based at least in part on the plurality of syndromes and the plurality of LLR magnitudes; and outputting the error vector.

Aspect 18: The method of aspect 17, wherein computing the error vector comprises: performing belief propagation on a tanner graph, wherein the tanner graph comprises a plurality of check nodes each corresponding to one of the plurality of syndromes and a plurality of variable nodes each corresponding to one of the plurality of LLR magnitudes.

Aspect 19: The method of any of aspects 17 through 18, wherein obtaining the plurality of syndromes and the plurality of LLR magnitudes comprises: obtaining a quantity of bits that is less than a product of a code length associated with the signal and a quantization level associated with the signal, wherein the quantity of bits is based at least in part on a coding rate of the signal.

Aspect 20: The method of any of aspects 17 through 19, wherein the decoder is a FEC decoder associated with a FEC code used to generate the plurality of encoded bits.

Aspect 21: An apparatus for wireless communications, comprising one or more memories storing processor-executable code, and one or more processors coupled with (e.g., operatively, communicatively, functionally, electronically, or electrically) the one or more memories and individually or collectively operable to execute the code (e.g., directly, indirectly, after pre-processing, without pre-processing) to cause the apparatus to perform a method of any of aspects 1 through 10.

Aspect 22: An apparatus for wireless communications, comprising at least one means for performing a method of any of aspects 1 through 10.

Aspect 23: A non-transitory computer-readable medium storing code for wireless communications, the code comprising instructions executable by one or more processors (e.g., directly, indirectly, after pre-processing, without pre-processing) to perform a method of any of aspects 1 through 10.

Aspect 24: A modem of a wireless device for wireless communications, comprising one or more memories storing processor-executable code, and one or more processors coupled with (e.g., operatively, communicatively, functionally, electronically, or electrically) the one or more memories and individually or collectively operable to execute the code (e.g., directly, indirectly, after pre-processing, without pre-processing) to cause the modem of a wireless device to perform a method of any of aspects 11 through 16.

Aspect 25: A modem of a wireless device for wireless communications, comprising at least one means for performing a method of any of aspects 11 through 16.

Aspect 26: A non-transitory computer-readable medium storing code for wireless communications, the code comprising instructions executable by one or more processors (e.g., directly, indirectly, after pre-processing, without pre-processing) to perform a method of any of aspects 11 through 16.

Aspect 27: A decoder for wireless communications, comprising one or more memories storing processor-executable code, and one or more processors coupled with (e.g., operatively, communicatively, functionally, electronically, or electrically) the one or more memories and individually or collectively operable to execute the code (e.g., directly, indirectly, after pre-processing, without pre-processing) to cause the decoder to perform a method of any of aspects 17 through 20.

Aspect 28: A decoder for wireless communications, comprising at least one means for performing a method of any of aspects 17 through 20.

Aspect 29: A non-transitory computer-readable medium storing code for wireless communications, the code comprising instructions executable by one or more processors (e.g., directly, indirectly, after pre-processing, without pre-processing) to perform a method of any of aspects 17 through 20.

It should be noted that the methods described herein describe possible implementations. The operations and the steps may be rearranged or otherwise modified and other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies, including future systems and radio technologies, not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, a GPU, a NPU, an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration). Any functions or operations described herein as being capable of being performed by a processor may be performed by multiple processors that, individually or collectively, are capable of performing the described functions or operations.

The functions described herein may be implemented using hardware, software executed by a processor, or any combination thereof. Software shall be construed broadly to mean instructions, instruction sets, code, code segments, program code, programs, subprograms, software modules, applications, software applications, software packages, routines, subroutines, objects, executables, threads of execution, procedures, or functions, whether referred to as software, firmware, middleware, microcode, hardware description language, or otherwise. If implemented using software executed by a processor, the functions may be stored as or transmitted using one or more instructions or code of a computer-readable medium. Other examples and implementations are within the scope of the disclosure and appended claims. For example, due to the nature of software, functions described herein may be implemented using software executed by a processor, hardware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, phase change memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk, and Blu-ray disc. Disks may reproduce data magnetically, and discs may reproduce data optically using lasers. Combinations of the above are also included within the scope of computer-readable media. Any functions or operations described herein as being capable of being performed by a memory may be performed by multiple memories that, individually or collectively, are capable of performing the described functions or operations.

As used herein, including in the claims, “or” as used in a list of items (e.g., including a list of items prefaced by a phrase such as “at least one of” or “one or more of”) indicates an inclusive list such that, for example, a list of at least one of A, B, or C means, e.g., A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.” As used herein, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone; A and B in combination; A and C in combination; B and C in combination; or A, B, and C in combination.

As used herein, including in the claims, the article “a” before a noun is open-ended and understood to refer to “at least one” of those nouns or “one or more” of those nouns. Thus, the terms “a,” “at least one,” “one or more,” and “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

The term “determine” or “determining” or “identify” or “identifying” encompasses a variety of actions and, therefore, “determining” or “identifying” can include calculating, computing, processing, deriving, investigating, looking up (such as via looking up in a table, a database or another data structure), ascertaining and the like. Also, “determining” or “identifying” can include receiving (such as receiving information or signaling, e.g., receiving information or signaling for determining, receiving information or signaling for identifying), accessing (such as accessing data in a memory, or accessing information) and the like. Also, “determining” or “identifying” can include resolving, obtaining, selecting, choosing, establishing and other such similar actions.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label or other subsequent reference label.

The description set forth herein, in connection with the appended drawings, describes example configurations and does not represent all the examples that may be implemented or that are within the scope of the claims. The term “example” used herein means “serving as an example, instance, or illustration” and not “preferred” or “advantageous over other examples.” The detailed description includes specific details for the purpose of providing an understanding of the described techniques. These techniques, however, may be practiced without these specific details. In some figures, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
one or more memories storing processor-executable code; and
one or more processors coupled with the one or more memories and individually or collectively operable to execute the code to cause the apparatus to:
receive a signal comprising a plurality of encoded bits;
generate, from the signal, a plurality of log likelihood ratios of the plurality of encoded bits, wherein the plurality of log likelihood ratios comprise a sign vector associated with the plurality of log likelihood ratios and a plurality of log likelihood ratio magnitudes associated with the plurality of log likelihood ratios;
compute a plurality of syndromes based at least in part on the sign vector;
compute an error vector based at least in part on the plurality of syndromes and the plurality of log likelihood ratio magnitudes; and
output a plurality of information bits based at least in part on the error vector and the sign vector.

2. The apparatus of claim 1, wherein the one or more processors are individually or collectively further operable to execute the code to cause the apparatus to:
output, to a decoder, the plurality of syndromes and the plurality of log likelihood ratio magnitudes, wherein computing the error vector comprises:
computing, by the decoder, the error vector based at least in part on the plurality of syndromes and the plurality of log likelihood ratio magnitudes.

3. The apparatus of claim 2, wherein, to output the plurality of syndromes and the plurality of log likelihood ratio magnitudes, the one or more processors are individually or collectively operable to execute the code to cause the apparatus to:
output a quantity of bits that is less than a product of a code length associated with the signal and a quantization level associated with the signal, wherein the quantity of bits is based at least in part on a coding rate of the signal.

4. The apparatus of claim 2, wherein the decoder is a forward error correction decoder associated with a forward error correction code used to generate the plurality of encoded bits.

5. The apparatus of claim 1, wherein the one or more processors are individually or collectively further operable to execute the code to cause the apparatus to:
output, by a decoder to a modem, the error vector, wherein outputting the plurality of information bits further comprises:
output, by the modem, the plurality of information bits based at least in part on the error vector.

6. The apparatus of claim 1, wherein, to compute the error vector, the one or more processors are individually or collectively operable to execute the code to cause the apparatus to:
perform belief propagation on a tanner graph, wherein the tanner graph comprises a plurality of check nodes each corresponding to one of the plurality of syndromes and a plurality of variable nodes each corresponding to one of the plurality of log likelihood ratio magnitudes.

7. The apparatus of claim 1, wherein, to output the plurality of information bits, the one or more processors are individually or collectively operable to execute the code to cause the apparatus to:
compute a codeword vector, wherein the codeword vector comprises a sum of the error vector and the sign vector.

8. The apparatus of claim 1, wherein, to receive the signal comprising the plurality of encoded bits, the one or more processors are individually or collectively operable to execute the code to cause the apparatus to:
receive the plurality of encoded bits comprising one or more punctured bits, wherein the sign vector is generated based at least in part on the one or more punctured bits.

9. The apparatus of claim 8, wherein, to generate the sign vector, the one or more processors are individually or collectively operable to execute the code to cause the apparatus to:
generate, using a random value generator, one or more sign values corresponding to each of the one or more punctured bits.

10. The apparatus of claim 8, wherein, to generate the sign vector, the one or more processors are individually or collectively operable to execute the code to cause the apparatus to:
generate the sign vector, wherein one or more values of the sign vector corresponding to the one or more punctured bits are equal to a predefined value.

11. A modem of a wireless device, comprising:
one or more memories storing processor-executable code; and
one or more processors coupled with the one or more memories and individually or collectively operable to execute the code to cause the modem of a wireless device to:
receive a signal comprising a plurality of encoded bits;
generate, from the signal, a plurality of log likelihood ratios of the plurality of encoded bits, wherein the plurality of log likelihood ratios comprise a sign vector associated with the plurality of log likelihood ratios and a plurality of log likelihood ratio magnitudes associated with the plurality of log likelihood ratios;
compute a plurality of syndromes based at least in part on the sign vector;
output the plurality of syndromes and the plurality of log likelihood ratio magnitudes;
obtain an error vector based at least in part on the plurality of syndromes and the plurality of log likelihood ratio magnitudes; and
output a plurality of information bits based at least in part on the error vector and the sign vector.

12. The modem of a wireless device of claim 11, wherein, to output the plurality of information bits, the one or more processors are individually or collectively operable to execute the code to cause the modem of a wireless device to:
compute a codeword vector, wherein the codeword vector comprises a sum of the error vector and the sign vector.

13. The modem of a wireless device of claim 11, wherein, to receive the signal comprising the plurality of encoded bits, the one or more processors are individually or collectively operable to execute the code to cause the modem of a wireless device to:
receive the plurality of encoded bits comprising one or more punctured bits, wherein generating the sign vector is based at least in part on the one or more punctured bits.

14. The modem of a wireless device of claim 13, wherein, to generate the sign vector, the one or more processors are individually or collectively operable to execute the code to cause the modem of a wireless device to:
generate, using a random value generator, one or more sign values corresponding to each of the one or more punctured bits.

15. The modem of a wireless device of claim 13, wherein, to generate the sign vector, the one or more processors are individually or collectively operable to execute the code to cause the modem of a wireless device to:
generate the sign vector, wherein one or more values of the sign vector corresponding to the one or more punctured bits are equal to 0.

16. The modem of a wireless device of claim 11, wherein, to output the plurality of syndromes and the plurality of log likelihood ratio magnitudes, the one or more processors are individually or collectively operable to execute the code to cause the modem of a wireless device to:
output a quantity of bits that is less than a product of a code length associated with the signal and a quantization level associated with the signal, wherein the quantity of bits is based at least in part on a coding rate of the signal.

17. A decoder, comprising:
one or more memories storing processor-executable code; and
one or more processors coupled with the one or more memories and individually or collectively operable to execute the code to cause the decoder to:
obtain a plurality of syndromes associated with a signal and a plurality of log likelihood ratio magnitudes that correspond to a plurality of log likelihood ratios associated with the signal, the signal comprising a plurality of encoded bits, wherein the plurality of log likelihood ratios and the plurality of syndromes are associated with the plurality of encoded bits;
compute an error vector based at least in part on the plurality of syndromes and the plurality of log likelihood ratio magnitudes; and
output the error vector.

18. The decoder of claim 17, wherein, to compute the error vector, the one or more processors are individually or collectively operable to execute the code to cause the decoder to:
perform belief propagation on a tanner graph, wherein the tanner graph comprises a plurality of check nodes each corresponding to one of the plurality of syndromes and a plurality of variable nodes each corresponding to one of the plurality of log likelihood ratio magnitudes.

19. The decoder of claim 17, wherein, to obtain the plurality of syndromes and the plurality of log likelihood ratio magnitudes, the one or more processors are individually or collectively operable to execute the code to cause the decoder to:
obtain a quantity of bits that is less than a product of a code length associated with the signal and a quantization level associated with the signal, wherein the quantity of bits is based at least in part on a coding rate of the signal.

20. The decoder of claim 17, wherein the decoder is a forward error correction decoder associated with a forward error correction code used to generate the plurality of encoded bits.
